(19) United States
(12) Patent Application Publication
(10) Pub. No.: US 2011/0256685 A1
(43) Pub. Date: Oct. 20, 2011

(54) METHOD OF MANUFACTURING SEMICONDUCTOR DEVICE

(75) Inventors: Takahiro SUZUKI, Tokyo (JP); Kouta NOSAKA, Tokyo (JP); Katuyuki OKAMASU, Tokyo (JP); Akira MURAKAMI, Tokyo (JP); Katuhiko KAWASUMI, Tokyo (JP)

(73) Assignee: ELPIDA MEMORY, INC, Tokyo (JP)

(21) Appl. No.: 13/085,999

(22) Filed: Apr. 13, 2011

(30) Foreign Application Priority Data
Apr. 15, 2010 (JP) 2010-094006

(51) Int. Cl. H01L 21/02; H01L 21/308

(52) U.S. Cl. 438/381; 438/694; 257/E21.011; 257/E21.231

(57) ABSTRACT

A film structure including at least one film is formed on a face of a semiconductor substrate and then a first mask with a pattern is formed on the film structure. A second mask is formed so as to cover the first mask over a bevel region. The film structure is etched using the first and second masks and thereafter the remaining first and second masks are removed away.

This application is based upon and claims the benefit of priority from Japanese Patent Application No. 2010-094006, filed on Apr. 16, 2010, the disclosure of which is incorporated herein in its entirety by reference.

### TECHNICAL FIELD

The invention relates to a method of manufacturing a semiconductor device.

### RELATED ART

A semiconductor substrate generally includes a bevel region (a region including a side face of the semiconductor substrate and an adjacent inclined plane thereto). FIG. 1 shows a conventional semiconductor substrate on which chips are formed. Chips 33 are formed on semiconductor substrate 31 which includes the bevel region corresponding to a region including a side face of semiconductor substrate 31 and an adjacent inclined plane thereto. In FIG. 1, one portion 32 of the bevel region is indicated in a broken line in a surrounded way.

Below, with reference to FIG. 2 to FIG. 7, one example of a conventional method of manufacturing a semiconductor device will be described. In FIG. 2 to FIG. 7, FIG. XA (X being 2 to 7) shows an enlarged cross-section of a memory cell section in semiconductor substrate 1 while FIG. XB shows an enlarged cross-section of one portion of a bevel region. Moreover, in FIG. 2 to FIG. 7, only given elements such as a contact plug and a bit line are shown and remaining elements beneath the given elements are omitted for the sake of clarity.

First, a MOS type transistor is formed on the semiconductor substrate. Next, bit line 6 is formed so as to connect to one of both impurity diffusion layers of the MOS type transistor and contact plug 7A is formed so as to connect to the other of both impurity diffusion layers of the MOS type transistor.

Thereafter, as shown in FIG. 2, interlayer insulating film 11 is formed so as to cover interlayer insulating film 7 covering a top face of semiconductor substrate 1. Interlayer insulating film 11 is made of a silicon nitride film deposited using a LP-CVD (low pressure CVD) method or an ALD (atomic layer deposition) method, and covers the side face and rear face of the semiconductor substrate.

DRAM chip with an operable circuit is formed in an inner region (effective chip region) excluding region F with a ring shape located at an outermost periphery of semiconductor substrate 1 as shown in FIG. 2B. The effective chip region is set to a more inner region than the bevel region (the region including the side face of the semiconductor substrate and the adjacent inclined plane thereto).

Speaking specifically, when a circular substrate with 300 mm diameter is employed as the semiconductor substrate, a width of region F is set to approximately 2 mm. In region F located outside of the effective chip region, capacitive contact pad 10 is removed during patterning process.

Next, as shown in FIG. 3, interlayer insulating film 12 made of silicon oxide is deposited with approximately 2 μm using a PE-CVD (plasma enhanced CVD) method. Thereafter, supporting film 14 made of silicon nitride is deposited with approximately 100 μm using a LP-CVD method or an ALD method. As shown in FIG. 3B, supporting film 14 covers the side face of the rear face of semiconductor substrate 1.

A hard mask layer is formed in order to form opening 12A used in forming a lower electrode of a capacitor. The hard mask layer has a stack structure in which carbon film 21 and ARL (anti-reflect layer) 22 are stacked one on top of the other. Carbon film 21 with 600 to 800 nm thickness is formed using a CVD method. ARL 22 functioning as an anti-reflection film made of a SiON film is formed with 15 to 100 nm thickness. ARL 22 further serves as a hard mask layer and thus material thereof is selected in order to have different etching rate from that of the carbon film in carrying out the dry etching.

A mask pattern for forming openings 12A at positions at which the capacitors will be formed is formed by performing a photolithography technique using photoresist film 23 formed on ARL 22. At this time, photoresist film 23 is formed in the effective chip region and region F outside thereof. As shown in FIG. 3B, in bevel region D, a normal mask pattern is not formed because the top face of semiconductor substrate 1 is curved.

Subsequently, as shown in FIG. 4, ARL 22 and carbon film 21 are sequentially patterned by performing anisotropic dry etching using photoresist film 23 as a mask. Since in bevel region D, photoresist film 23 collapses, the entirety of ARL 22 and carbon film 21 is not removed but only portions thereof are removed away. In such an anisotropic dry etching, photoresist film 23 also is removed at the same time as the etching and removal of the carbon film because carbon film 21 and photoresist film 23 are made of organic material. A shape of the mask pattern is sustained with ARL 22.

Next, as shown in FIG. 5, openings 12A (corresponding to capacitor holes) are formed so as to penetrate through supporting film 14 and interlayer insulating films 12, 11 by performing anisotropic dry etching using as a mask ARL 22 and carbon film 21. At the same time, trench 12B (refer to FIG. 10 and FIG. 12; corresponding to trench for a guard ring) is formed in the outside region of the memory cell section. At bottoms of openings 12A and trench 12B, the top faces of capacitive contact pads 10 are exposed. When performing the dry etching for forming openings 12A, ARL 22 also is etched and removed away. The shape of the mask pattern is sustained with carbon film 21.

After forming openings 12A and trench 12B, carbon film 21 is removed by performing a plasma ashing process using oxygen gas. In bevel region D, as mentioned above, some portions of supporting film 14 and interlayer insulating film 10 are removed because of the pattern collapse.

Thereafter, as shown in FIG. 6, titanium nitride film as lower electrode 13 of the capacitor is formed with such a thickness not to completely fill openings 12A. The material of lower electrode 13 may employ other metal films than the titanium nitride film. At the same time as the formation of the lower electrode in the openings, lower electrode 13 is formed in trench 12B. Lower electrode 13 on supporting film 14 is removed with a CMP method or etching-back, so that lower electrode 13 remains only on the inner walls of openings 12A and trench 12B.

In a following time, as shown in FIG. 7, support 14S is formed by patterning supporting film 14 using as a mask the pattern formed using the photoresist film. Support 14S contacts with a portion of the side face of lower electrode 13 and supports the side face of lower electrode 13, resulting in preventing the lower electrode from collapsing in a subsequent wet etching process.

Support 14S is disposed in a stripe pattern extending in an X direction (refer to FIG. 10) on the photoresist mask. Supporting film (made of the silicon nitride film) 14 is not formed in openings 12A from the beginning, and, therefore, support 14S formed finally by being transferred from the photomask pattern exists only in regions out of openings 12A.

Support 14S couples each other neighboring lower electrodes in extending direction thereof and extends up to the end of the memory cell section. At the end of the memory cell section, support 14S is coupled to the side face of lower electrode 13 formed as the guard ring in trench 12B.

Moreover, supporting film 14 covers the top face of a peripheral circuit section and thus prevents chemical solution or etchant (hydrofluoric acid) from invading the peripheral circuit section during a subsequent wet etching. In bevel region D, the photoresist film pattern may collapse, thereby removing away some portion of supporting film 14.

Thereafter, as shown in FIG. 8, by performing the wet etching using the chemical solution or etchant (hydrofluoric acid), interlayer insulating film 12 is removed in the memory cell section, so that the outer wall of lower electrode 13 is exposed. In such a wet etching, interlayer insulating film 11 made of the silicon nitride film serves as a stopper film so as to prevent the underlying device from being etched.

In the region out of the memory cell section, supporting film 14 deposited on the top face of interlayer insulating film 12 is not removed but remains and further the side wall thereof is protected with lower electrode 13 formed as the guard ring in trench 12B, and the top face thereof is covered with supporting film 14, thereby preventing the etchant used in the wet etching process from invading the region out of the memory cell section. Lower electrode 13 of the capacitor is supported with support 14S in such a way not to collapse in the wet etching process.

As for the resultant semiconductor device, Japanese Patent Laid-Open No. 2002-334879 and 2004-103768 set forth approaches for preventing the insulting film or the conductive film remaining in the bevel region of the semiconductor substrate during forming a semiconductor chip (hereinafter, often referred to as “chip”) on the semiconductor substrate.

Moreover, Japanese Patent Laid-Open No. 2008-283026 sets forth an approach for preventing the capacitor electrode for the memory cell from collapsing using an insulating film when forming the chip with DRAM function.

### SUMMARY OF THE INVENTION

In one embodiment, there is provided a method of manufacturing a semiconductor device, comprising:

preparing a semiconductor substrate;

forming a film structure comprising at least one film on a primary face comprising a bevel region of the semiconductor substrate;

forming a first mask with a pattern on a face of the film structure;

forming a second mask over the bevel region so as to cover the first mask;

etching the film structure using the first and second masks so that the film structure remains in the bevel region and a region of the semiconductor substrate other than the bevel region; and

removing the first and second masks which remain.

In another embodiment, there is provided method of manufacturing a semiconductor device, comprising:

forming an interlayer insulating film on a semiconductor substrate;

sequentially depositing a carbon film and an anti-reflection film on a face of the interlayer insulating film and then patterning the deposited films, to form a first mask;

removing the anti-reflection film over a bevel region of the semiconductor substrate, to expose the carbon film;

forming a second mask containing a negative photoresist film so as to cover a portion of an exposed carbon film in the bevel region of the semiconductor substrate;

performing a dry etching using a mask pattern formed in the first mask, to pattern the interlayer insulating film in a region not covered with the second mask; and

removing the first and second masks which remain.

In another embodiment, there is provided method of manufacturing a semiconductor device, comprising:

forming an interlayer insulating film on a semiconductor substrate;

sequentially depositing a carbon film and an anti-reflection film on a face of the interlayer insulating film and then patterning the deposited films, to form a first mask;

forming a second mask containing negative photoresist on the first mask over a bevel region of the semiconductor substrate;

patterning the interlayer insulating film using the first and second masks as a mask;

removing the anti-reflection layer in a region of the semiconductor substrate not covered with the second mask;

removing the carbon film in a region of the semiconductor substrate not covered with the second mask, and removing a portion of the second mask to expose the anti-reflection layer over the bevel region;

removing the anti-reflection layer exposed over the bevel region; and

removing the carbon film and the second mask remaining over the bevel region.

### BRIEF DESCRIPTION OF THE ACCOMPANYING DRAWINGS

The above features and advantages of the present invention will be more apparent from the following description of certain preferred embodiments taken in conjunction with the accompanying drawings, in which:

FIG. 1 to FIG. 8 illustrate a conventional method of manufacturing a semiconductor device;

FIG. 9 to FIG. 27 illustrate a method of manufacturing a semiconductor device according to a first exemplary embodiment;

FIG. 28 to FIG. 34 illustrate a method of manufacturing a semiconductor device according to a second exemplary embodiment; and

FIG. 35 is a graph illustrating evaluation results of the semiconductor devices according to the conventional example, the first and second exemplary embodiments and a third exemplary embodiment.

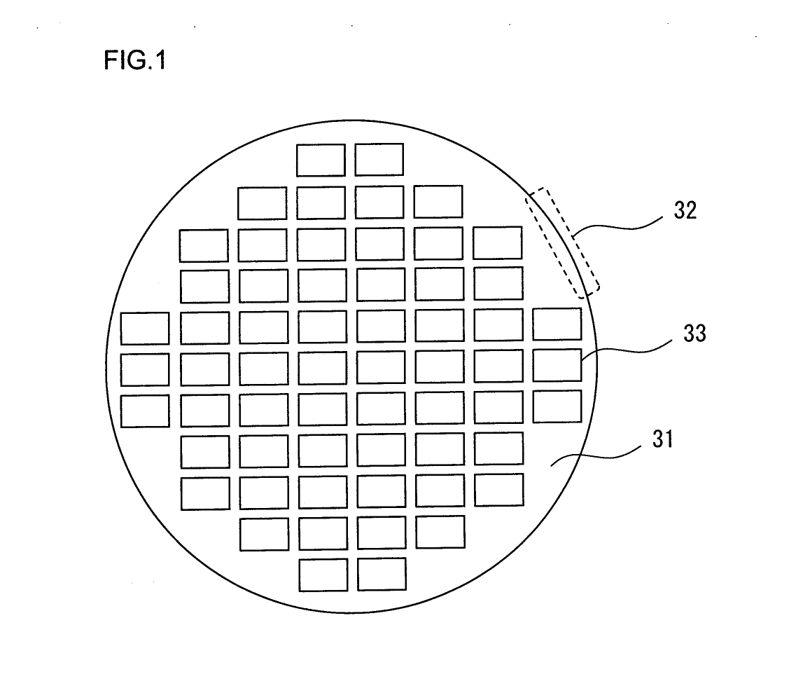

In the drawings, reference numerals have the following meanings: 1, 31; semiconductor substrate, 2; a hole pattern, 3; isolation region, 4, 7, 11, 12, 40; interlayer insulating film; 4A; bit line contact plug, 5; gate electrode, 5a; gate insulating film, 5b; side wall, 5c; insulating film, 6; bit line, 7A; capacitive contact plug, 8; impurity diffusion layer, 9; substrate contact plug, 10; capacitive contact pad, 12A; opening; 12B; trench for guard ring, 13, 13b; lower electrode, 14; supporting film, 14S; support; 15; upper electrode, 21; carbon film, 22; ARL (anti-reflect layer), 23; photoresist film, 32; bevel region, 33; semiconductor chip, 35; bevel mask layer, 39; gate interlayer insulating film, 41; wire layer, 42; surface protection film, 50; DRAM chip, 51; memory cell section, 52; peripheral circuit section, 205a, 205b, 205c; substrate contact region. Ca; capacitor (capacitive device), D; bevel region; K; active region, Tr; MOS type transistor, and W; word line.

### DETAILED DESCRIPTION OF THE EXEMPLARY EMBODIMENTS

In a method of manufacturing a semiconductor device, a second mask covering a first mask on a bevel region is formed in order to prevent the first mask over the bevel region from collapsing. Next, a film structure is etched by performing etching process using the first mask etc. and then a remaining first mask etc. is removed away. In such an etching process, the first mask over the bevel region is not collapsed due to the second mask covering the first mask. Therefore, the film structure beneath the first mask, after removing the first mask, may be prevented from peeling off. As a result, reduction of producing yield of the semiconductor device may be suppressed, and increase of manufacturing cost may be suppressed.

Meanwhile, “film structure” refers to a structure in which one film or a plurality of films is/are formed on the semiconductor substrate. A wiring structure such as a contact plug or a bit line, or a pad may be buried in the film structure.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

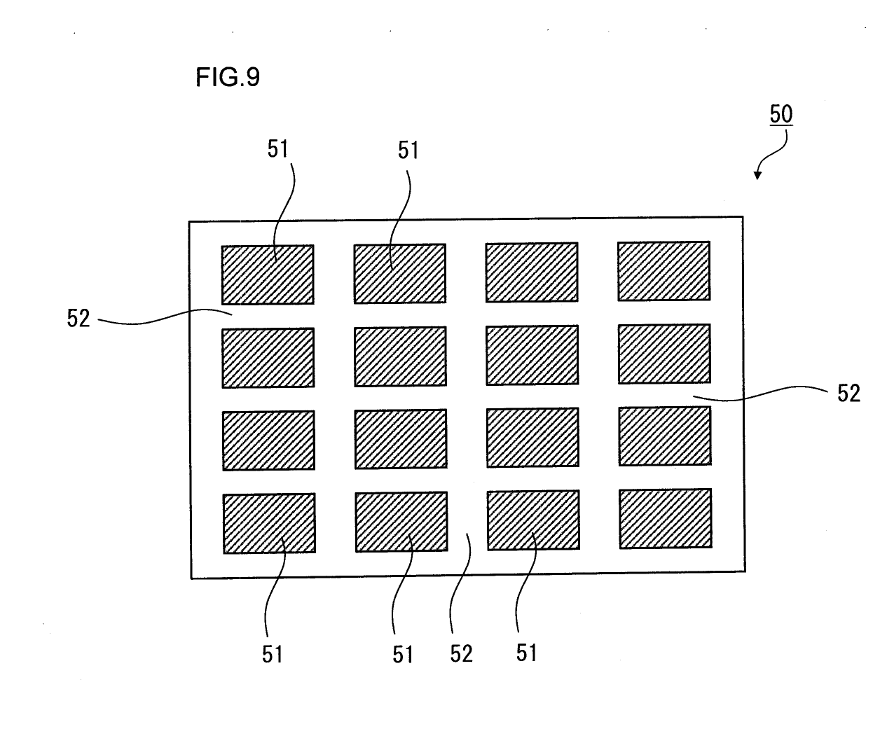

A configuration of a memory cell including a capacitor of a semiconductor device according to this exemplary embodiment will be described with reference to the related drawings. A DRAM chip as the semiconductor device includes in a schematic way a memory cell section and a peripheral circuit section. FIG. 9 is a top view of the DRAM chip. The DRAM chip 50 includes a plurality of arranged memory cell sections 51 and peripheral circuit sections 52 surrounding memory cell sections 51. Peripheral circuit sections 52 may include a sense amplifier circuit, a word-line driving circuit, an input/output circuit from/to an external, etc. The layout in FIG. 9 is merely one example, and, accordingly, the number of the memory cell sections or the positions of the memory cell sections are not limited to the layout in FIG. 9.

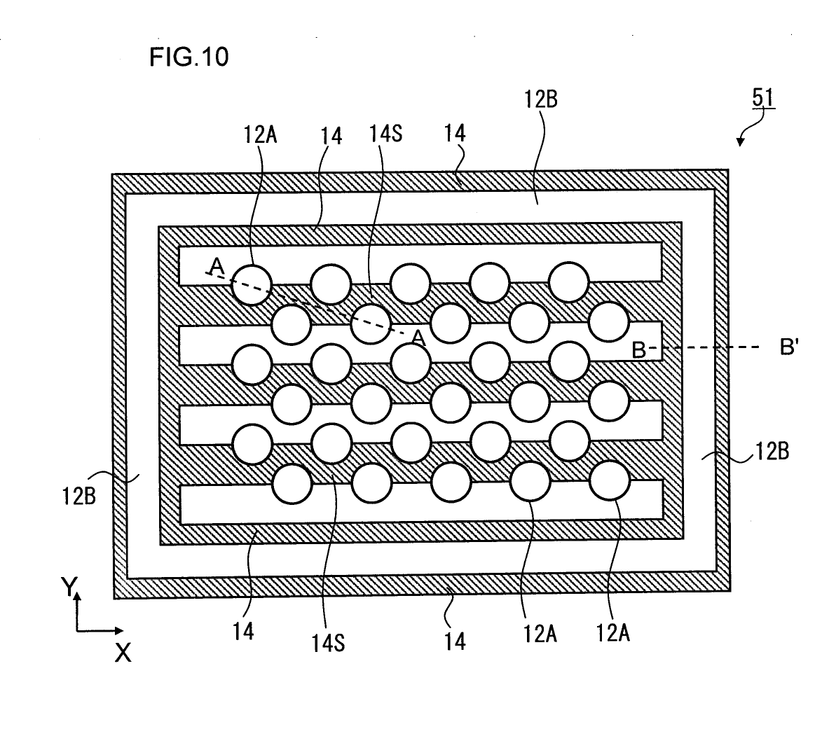

FIG. 10 is a top view of an entirety of one memory cell section 51 and shows only some components included in memory cells. Trench 12B functioning as the guard ring is formed in an outer peripheral region of memory cell section 51 so as to surround the memory cell section. Reference numerals 12A indicate position at which lower electrode of the capacitor included in each memory cell is formed. Reference numerals 14S indicate supports for preventing the lower electrodes of the capacitors from collapsing during the manufacturing process of the semiconductor device and are formed by patterning supporting films 14 covering the memory cell section. Here, supports 14S have line patterns extending in a lateral (X) direction on the drawing. Supports 14S contact with side walls (outer walls) of the lower electrodes formed at positions 12A. Supporting films 14 are formed so as to be in a contact with the side walls of the trench 12B.

The layout of the capacitors in FIG. 10 is merely one example, and, accordingly, the number of the capacitors or the positions of the capacitors are not limited to the layout in FIG. 10. The arrangement pattern of supports 14S is merely one example and therefore the extending direction thereof is not limited to that in FIG. 10.

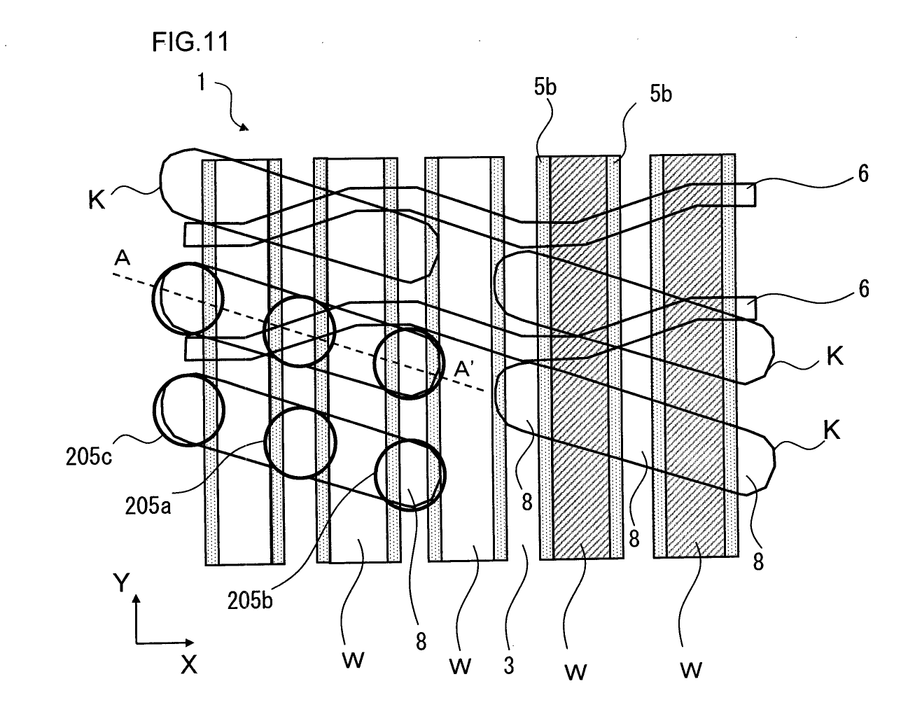

FIG. 11 is a detailed top view of each memory cell of a plurality of the memory cells arranged in memory cell section 51 and shows only some components included in each memory cell.

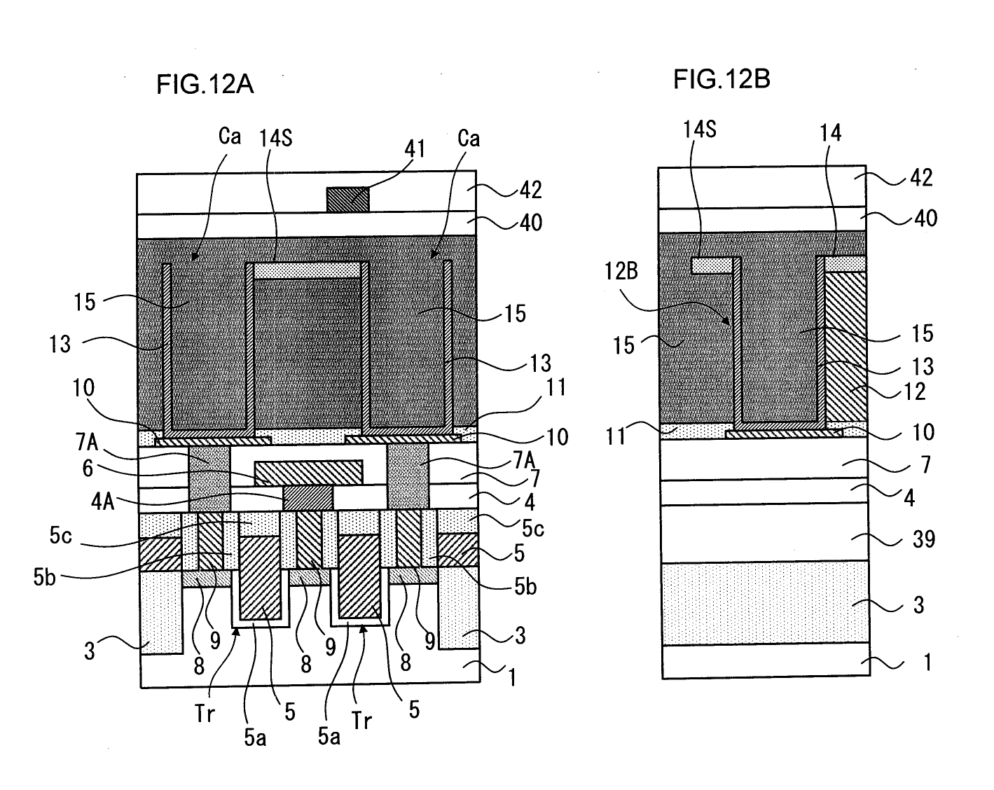

FIG. 12A is a cross-sectional view of a memory cell taken at a line A-A′ in FIG. 10 and FIG. 11. FIG. 12B is a cross-sectional view of the guard ring taken a line B-B′ in FIG. 10. Those drawings are provided in the way of example to illustrate the configuration of the semiconductor device. Dimension or size of each portion as shown may be different from that of a real semiconductor device. In the right side of FIG. 11, active region K and bit line 6 are show transparently with the top view taken at a plane cutting gate electrode 5 and side wall 5b to be word line W as described later.

As shown in FIG. 12A, the memory cell roughly includes MOS type transistor Tr for a memory cell and capacitor Ca connected to MOS type transistor Tr through a plurality of contact plugs. For the simplicity of the drawing, capacitor Ca is not shown in FIG. 11.

As shown in FIG. 11 and FIG. 12A, semiconductor substrate 1 is made of silicon containing P type impurities with a predetermined concentration. Isolation region 3 is formed in semiconductor substrate 1. Isolation region 3 is formed in other region than active region K by burying an insulating film such as a silicon oxide (SiO₂) film in the surface of semiconductor substrate 1 using STI (shallow trench isolation) method, in such a way to separate in an insulating way neighboring active regions K from each other. In FIG. 12A, the cell structure in which two bit memory cells are formed in one active region K is shown in the way of an example.

As shown in the top view of FIG. 11, in the memory cell section, a plurality of elongate strip-like active regions K are arranged in a parallel way to each other so as to be spaced with each other with a given distance and to extend obliquely toward the right side. Impurities diffusion layers are individually formed in both ends and a center region of each active region K so as to function as the source/drain electrodes of MOS type transistor Tr. Positions corresponding to substrate contact portions 205a, 205b and 205c are defined so as to be disposed right over the source/drain electrodes (impurities diffusion layers).

Meanwhile, the arrangement of active regions K is not limited to that in FIG. 11. The shape of active region K as shown in FIG. 11 may be other shapes of the active region generally applied to a common transistor. Moreover, isolation region 3 may be formed using different methods from the STI method.

As shown in FIG. 11, each of a plurality of bit lines 6 extends in a lateral (X) direction in a curved shape or bended shape and the plurality of bit lines 6 are arranged so as to be spaced from each other with a predetermined distance in a vertical (Y) direction of FIG. 11. Moreover, there are arranged a plurality of word lines W each of which extends in the vertical (Y) direction in a straight shape and the plurality of word lines W are arranged so as to be spaced from each other with a predetermined distance in the lateral (X) direction of FIG. 11. Word lines W are configured to have gate electrodes 5 as shown in FIG. 12A at intersecting positions between word lines W and active regions K. Here, the case in which MOS type transistor Tr includes the groove shape gate electrode is illustrated by the way of an example. Instead of such a MOS type transistor with the groove shape gate electrode, a planar MOS type transistor or a vertical MOS type transistor may be employed, or there may be employed a MOS type transistor in which a channel region is formed in a side face of a groove provided in the semiconductor substrate.

As shown in the cross-section of FIG. 12A, impurities diffusion layers 8 acting as the source/drain electrodes are formed in a separated way from each other in active region K partitioned with isolation region 3 in semiconductor substrate 1. Groove shape gate electrodes 5 are formed between impurities diffusion layers 8 respectively. Gate electrodes 5 are made of a stack of a polysilicon film and a metal film so as to protrude upward from semiconductor substrate 1. The polysilicon film employed in gate electrodes 5 may be doped with impurities such as phosphorus while being formed using a CVD (chemical vapor deposition) method. Otherwise, the polysilicon film has been formed using the CVD method without the doping of the impurities, and, thereafter, the N or P type impurities may be implanted into the polysilicon film using an ion implanting method. The metal film used in the gate electrode may employ metals with refractory metal such as tungsten (W), tungsten nitride (WN) or tungsten silicide (WSi).

As shown in FIG. 12A, gate insulating film 5a is formed between gate electrode 5 and semiconductor substrate 1. Side wall 5b made of an insulating film such as silicon nitride (Si₃N₄) is formed on the side wall of gate electrode 5. Insulating film 5c made of silicon nitride is formed on the top face of gate electrode 5.

Impurities diffusion layers 8 are formed by doping the N type impurities such as phosphorus into active region K provided in semiconductor substrate 1. Gate interlayer insulating film 39 (not shown in FIG. 12A) made of silicon oxide is formed so as to fill in between the gate electrodes. Substrate contact plugs 9 are formed so as to be in a contact with impurities diffusion layers 8. Substrate contact plugs 9 are disposed respectively at the positions corresponding to substrate contact portions 205a, 205b and 205c as shown in FIG. 11, and are made of polysilicon containing, for example, phosphorus. Substrate contact plugs 9 are formed in a self-alignment manner so that a lateral (X directional) width thereof is defined by side walls 5b provided to gate wires W adjacent to the substrate contact plugs.

As shown in FIG. 12A, interlayer insulating film 4 is formed so as to cover insulating film 5c on the top face of the gate electrode and to cover the top face of the substrate contact plugs. Bit line contact plug 4A is formed so as to penetrate through interlayer insulating film 4. Bit line contact plug 4A is disposed over substrate contact portion 205a and is electrically connected to substrate contact plug 9. Bit line contact plug 4A has a stack structure in which a tungsten (W) film is stacked on a barrier film (TiN/Ti film) made of a stack of a Ti film and a TiN film. Bit line 6 is formed so as to connect to bit line contact plug 4A. Bit line 6 is made of a stack of a tungsten nitride (WN) film and a tungsten (W) film.

Interlayer insulating film 7 is formed so as to cover bit line 6. Capacitive contact plugs 7A are formed so as to penetrate through interlayer insulating films 4, 7 and to be electrically connected to substrate contact plugs 9. Capacitive contact plugs 7A are disposed over substrate contact portions 205b, 205c.

Capacitive contact pads 10 are disposed on interlayer insulating film 7 and are electrically connected to capacitive contact plugs 7A respectively. Capacitive contact pads 10 are a stack of a WN (tungsten nitride) film and a W (tungsten) film. Capacitive contact pad 10 is formed in the guard ring region so as to surround the memory cell section with its ring shape.

Interlayer insulating film 11 made of silicon nitride is formed so as to cover capacitive contact pads 10. Capacitors Ca are formed so as to penetrate through interlayer insulating film 11 and to be electrically connected to capacitive contact pads 10. Capacitors Ca are configured so that capacitive insulting film (not shown) is sandwiched between lower electrode 13 and upper electrode 15 and lower electrode 13 is electrically connected to capacitive contact pad 10A. Support 14S is formed in order to support the side wall of lower electrode 13 and thus prevent the lower electrode from collapsing during the manufacturing process. Support 14S is formed by patterning supporting film 14 made of silicon nitride (Si₃N₄).

As shown in FIG. 12B, trench 12B is formed in the outer peripheral region of the memory cell section so as to penetrate through interlayer insulating films 12, 11. Lower electrode 13 of the capacitor is formed on the inner wall of trench 12B to act as the guard ring. Such surrounding of the memory cell section with trench 12B prevents the etchant or chemical solution used in the wet etching process for exposing the lower electrode of the capacitor from invading the peripheral circuit section in the lateral direction. Lower electrode 13 formed in trench 12B does not function as the element of the capacitor but is formed at the same time as the formation of the lower electrode in the memory cell section. Accordingly, in a following description, lower electrode 13 formed in trench 12B will be also referred to as the lower electrode without distinguishing it from the lower electrode in the memory cell region.

The capacitor for memory function is not formed in the peripheral circuit section (more outer region than trench 12B in FIG. 10) of the DRAM chip in which interlayer insulating film 12 made of silicon oxide is formed over the interlayer insulating film 11. Supporting film 14 remains so as to cover the top face of the peripheral circuit section until at least the wet etching process for exposing the lower electrode of the capacitor has been terminated, thereby preventing the etchant used in the wet etching process from invading the peripheral circuit section from the top.

As shown in FIG. 12A, in the memory cell section, interlayer insulating film 40 is formed over capacitors Ca, and upper wire layer 41 made of aluminum (Al) or copper (Cu) and surface protection film 42 are formed on interlayer insulating film 40.

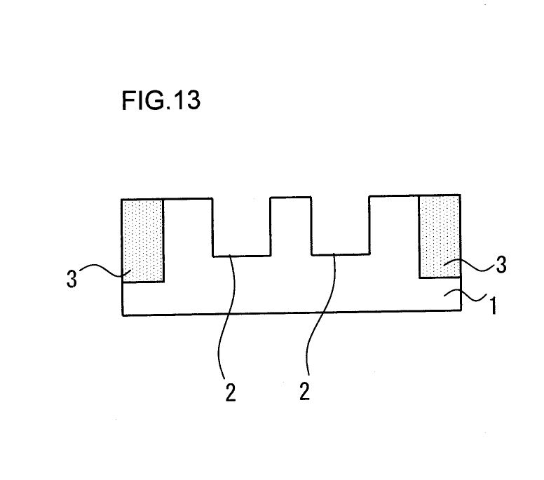

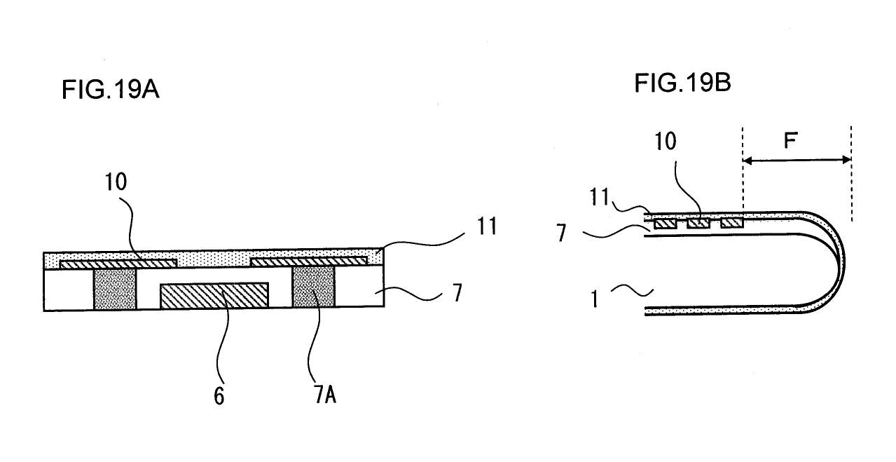

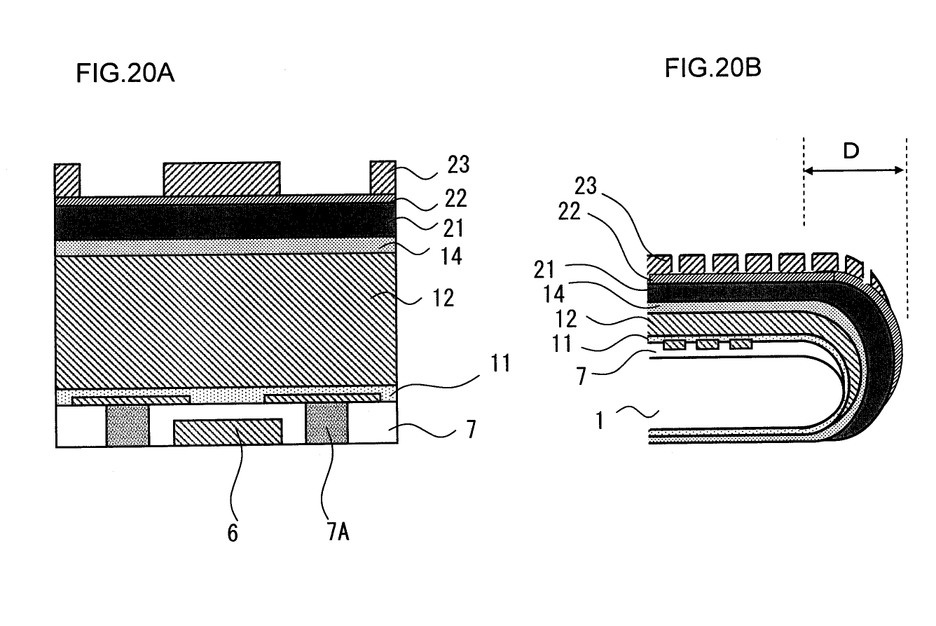

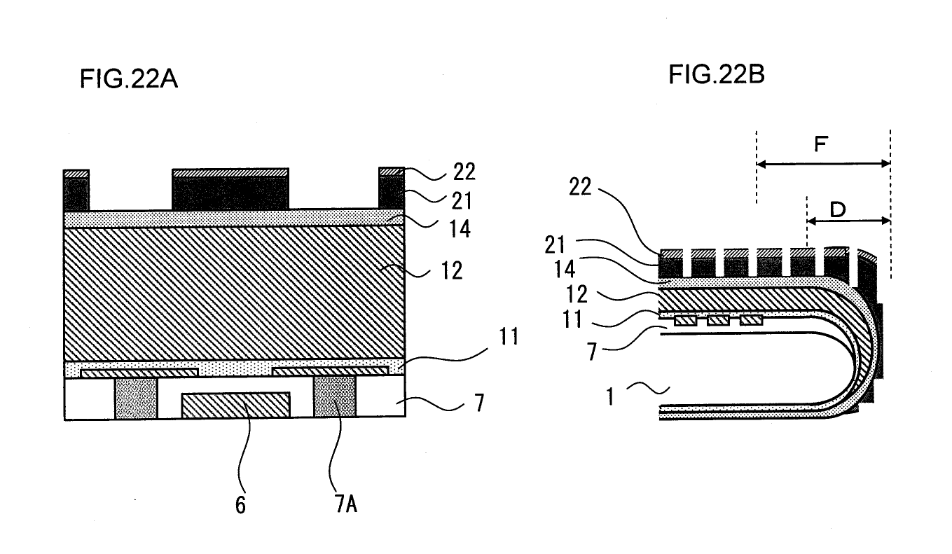

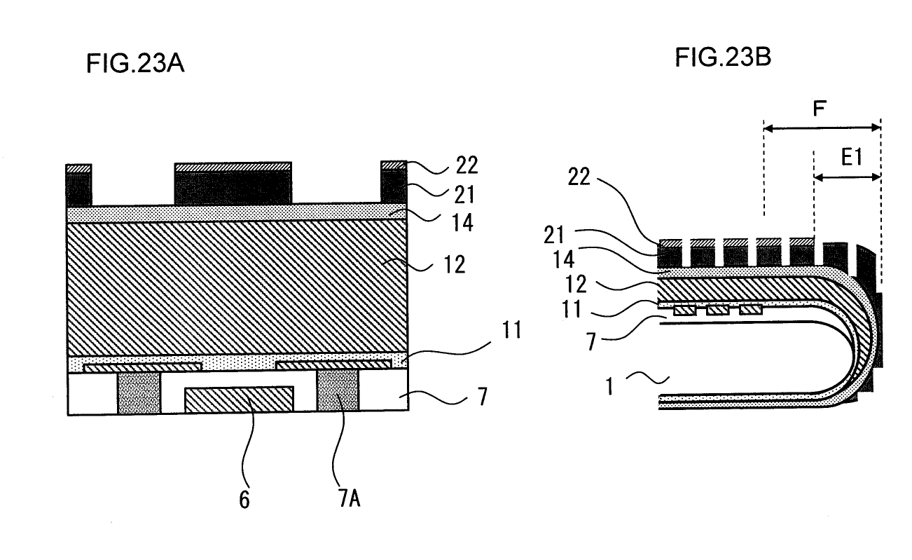

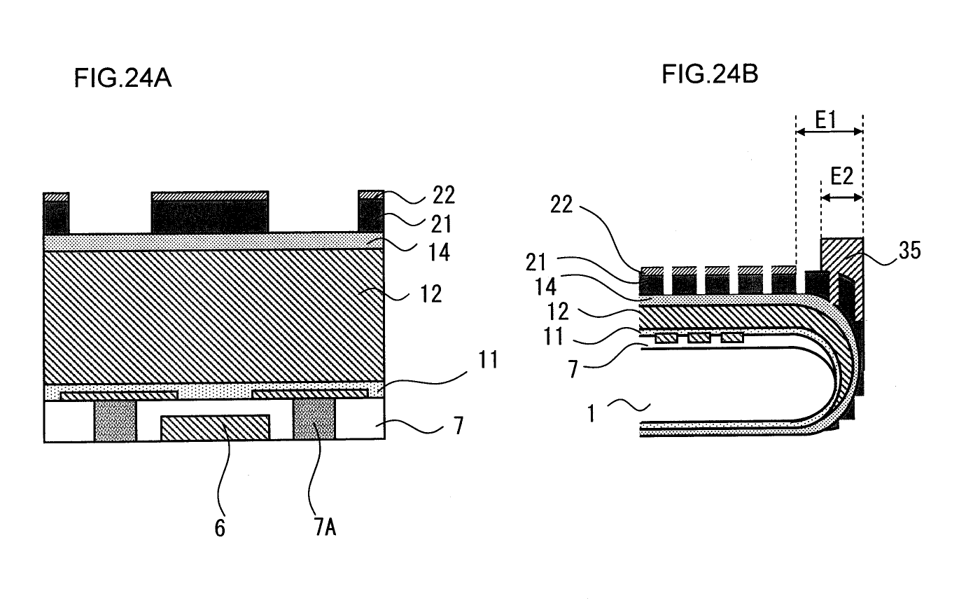

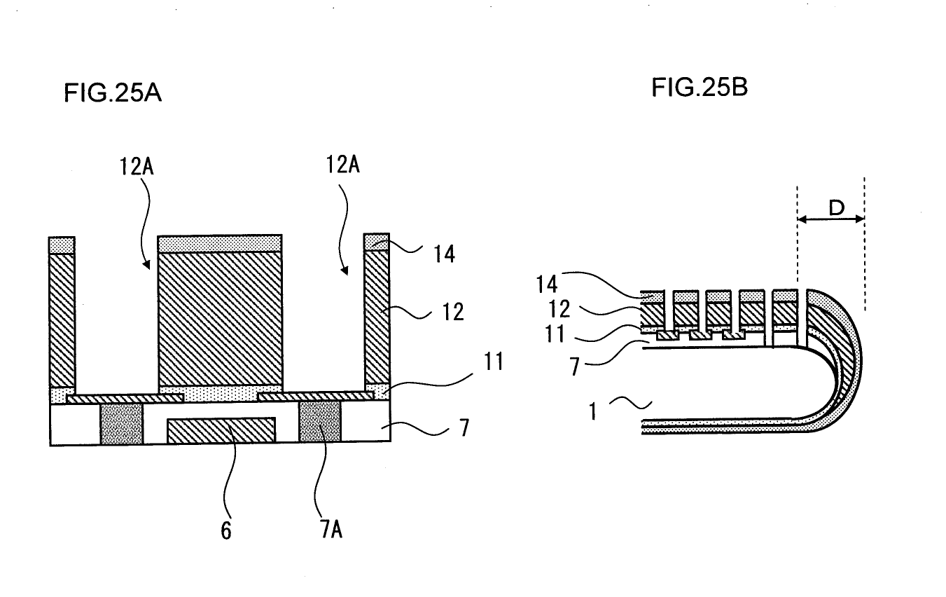

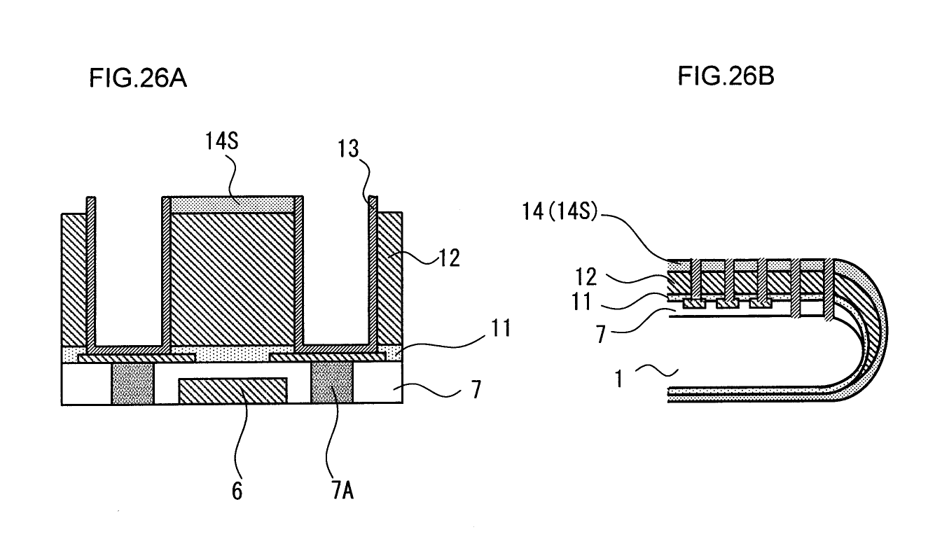

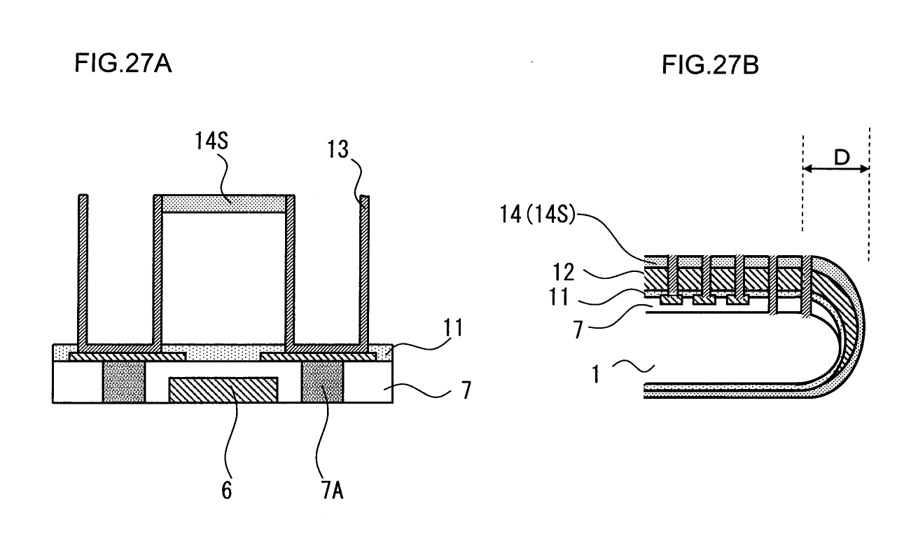

Next, regarding the method of manufacturing the DRAM chip according to this exemplary embodiment, the processes taken in forming up to interlayer insulating film 11 will be described with reference to FIG. 13 to FIG. 27. FIG. 13 to FIG. 18, FIG. 19A, FIG. 20A, FIG. 22A, FIG. 23A, FIG. 24A, FIG. 25A, FIG. 26A and FIG. 27A are cross-sectional views of the memory cell section taken in a line A-A′ in FIG. 10 and FIG. 11. In FIG. 19A, FIG. 20A, FIG. 22A, FIG. 23A, FIG. 24A, FIG. 25A, FIG. 26A and FIG. 27A, the structure beneath bit line 6 and contact plug 7A will be omitted. FIG. 19B, FIG. 20B, FIG. 22B, FIG. 23B, FIG. 24B, FIG. 25B, FIGS. 26B and FIG. 27B are cross-sectional views of the bevel region. In FIG. 19B, FIG. 20B, FIG. 22B, FIG. 23B, FIG. 24B, FIG. 25B, FIGS. 26B and FIG. 27B, only important members are shown. The guard ring section is formed at the same time as the formation of the memory cell section if a specific otherwise description is not mentioned. Meanwhile, MOS type transistor Tr is not formed in the guard ring region which serves as isolation region 3.

Moreover, in the following description, interlayer insulating films 39, 4, 7, 11, 12 and supporting film 14 forms a film structure, and contact plugs 4A, 7A, 9, bit line 6 and pad 10 are buried in the film structure.

As shown in FIG. 13, in order to partition active regions K in the primary face of semiconductor substrate 1 made of P type silicon, isolation region 3 is formed in the region excluding active regions K by burying therein an insulating film such as silicon oxide (SiO₂) using a STI method. Next, groove pattern 2 for gate electrode of MOS type transistor Tr is formed. Groove pattern 2 is formed by etching silicon of semiconductor substrate 1 using as mask a pattern (not shown) made of photoresist.

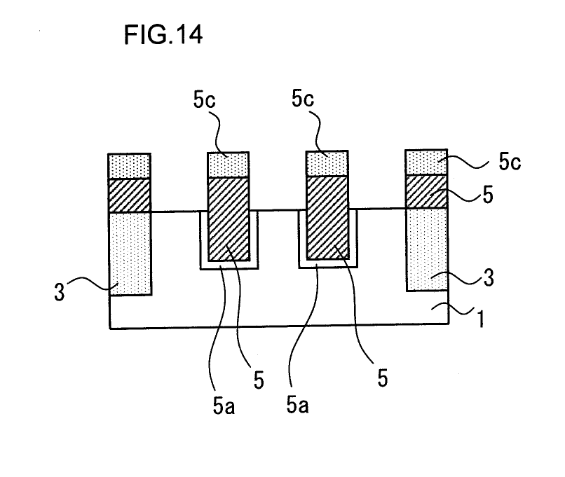

Next, as shown in FIG. 14, gate insulating film 5a with 4 nm thickness made of silicon oxide is formed in transistor forming regions by oxidizing the silicon surface of semiconductor substrate 1 using a thermal oxidation method and thus forming silicon oxide. The gate insulating film may employ a stack of an silicon oxide film and a silicon nitride film or a High-K film (high dielectric film). Thereafter, a polysilicon film containing N type impurities is deposited on gate insulating film 5a by performing a CVD method using monosilane (SiH₄) and phosphine (PH₃) as source gas. At this time, the deposited polysilicon film has such a thickness that the entire inner space of groove pattern 2 for the gate electrode is completely filled with the polysilicon film. Otherwise, the polysilicon film not containing the impurities such as phosphorus is formed and next desired impurities are implanted into the polysilicon film using an ion implanting method.

Subsequently, there is formed a metal stack film with 50 nm thickness in which for example a tungsten silicide film, a tungsten nitride film and a tungsten film as metal films are deposited sequentially on the polysilicon using a sputtering method. The polysilicon film and the metal stack film are subjected to following processes to form gate electrode 5.

Next, insulating film 5c made of silicon nitride with 70 nm thickness is deposited on the metal stack film for forming gate electrode 5 by performing a plasma CVD method using monosilane (SiH₄) and ammonia (NH₃) as source gas. Then, photoresist pattern for forming gate electrode 5 is formed by applying a photoresist film (not shown) on insulating film 5c and then patterning the applied film with a photolithography technique using a mask for forming gate electrode 5. Thereafter, insulating film 5c is etched by performing a anisotropic etching using the photoresist pattern as a mask. After removing the photoresist pattern, the metal stack film and polysilicon film are etched away using insulating film 5c as a hard mask, thereby forming gate electrode 5. Gate electrode 5 functions as word line W (refer to FIG. 11).

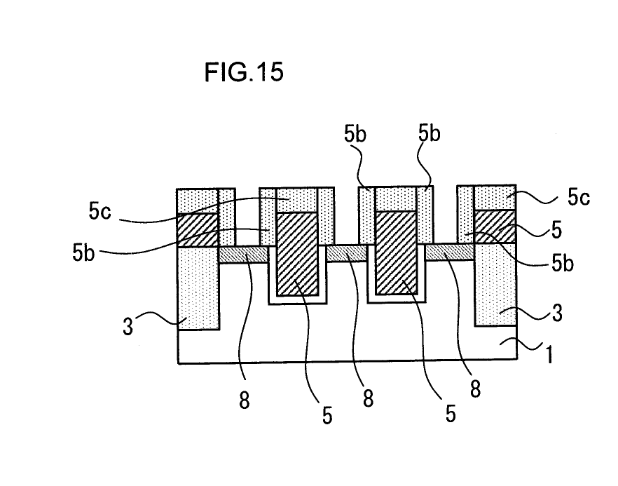

Thereafter, as shown in FIG. 15, impurities diffusion layers 8 are formed in some of the active region which is not covered with gate electrode 5 by performing the ion implanting of phosphorus as the N type impurities. Then, using the CVD method, a silicon nitride film with 20 to 50 nm thickness is deposited on the entire surface of the resultant structure. Next, side wall 5b is formed on the side wall of gate electrode 5 by etching back the deposited film.

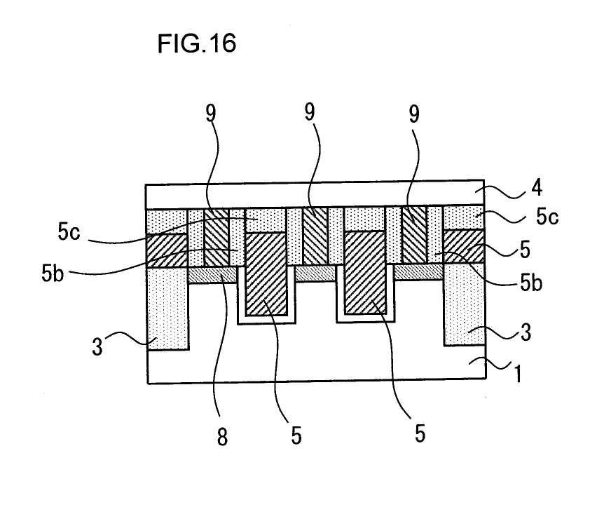

Next, as shown in FIG. 16, interlayer insulating film 39 (refer to FIG. 12B) made of silicon oxide is formed using a CVD method so as to cover insulating film 5c on the top face of the gate electrode and to cover side wall insulating film 5b. Then, in order to planarize concave-convex portions resulting from gate electrode 5, the surface of interlayer insulating film 39 is polished using a CMP (chemical mechanical polishing) method. The polishing stops at the time when the top face of insulating film 5c on the top face of gate electrode begins to be exposed.

Thereafter, substrate contact plugs 9 are formed. To be specific, first, the previously formed interlayer insulating film is etched away and removed by etching it using a pattern made of photoresist as a mask so that openings are formed at the positions corresponding to substrate contact portions 205a, 205b, 205c as shown in FIG. 11. The openings (contact holes) are formed between gate electrodes 5 in a self-alignment manner using insulating films 5b, 5c made of the silicon nitride. Next, a polysilicon film containing phosphorus is deposited using the CVD method and then the deposited film is polished using the CMP method to remove the polysilicon film on the top face of insulating film 5c, resulting in forming substrate contact plugs 9 filled in the openings.

Subsequently, interlayer insulating film 4 made of silicon oxide with for example 600 nm thickness is formed using the CVD method so as to cover insulating film 5c on the top face of the gate electrode and to cover the top face of substrate contact plugs 9. Next, the surface of interlayer insulating film 4 is polished away and planarized using the CMP method until the thickness of interlayer insulating film 4 becomes for example 300 nm.

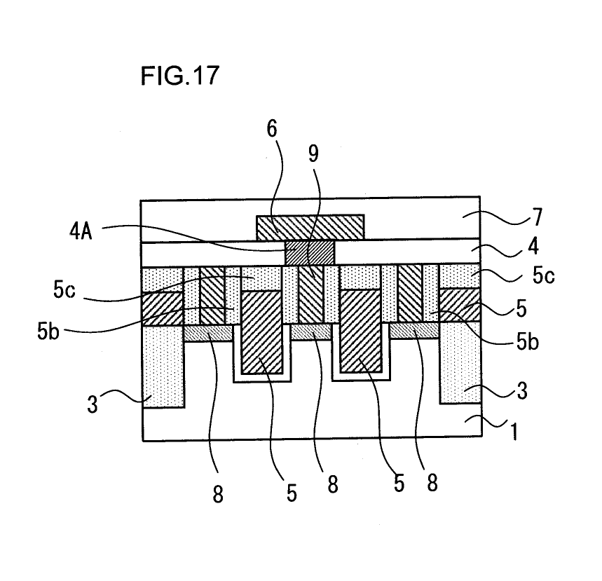

Next, as shown in FIG. 17, opening (contact hole) is formed in interlayer insulating film 4 and at an upper position of substrate contact portion 205a as shown in FIG. 11 so as to expose the surface of substrate contact plug 9. A stack film in which a W (tungsten) film is stacked on a barrier film such as a TiN/Ti film is deposited so as to fill the inner space of the opening, and then the surface of the resultant structure is polished away using the CMP method, thereby forming bit line contact plug 4A. Thereafter, bit line 6 is formed so as to be electrically connected to bit line contact plug 4A. Interlayer insulating film 7 made of silicon oxide is formed so as to cover bit line 6. Those interlayer insulating films 39, 4 and 7 correspond to first interlayer insulating film.

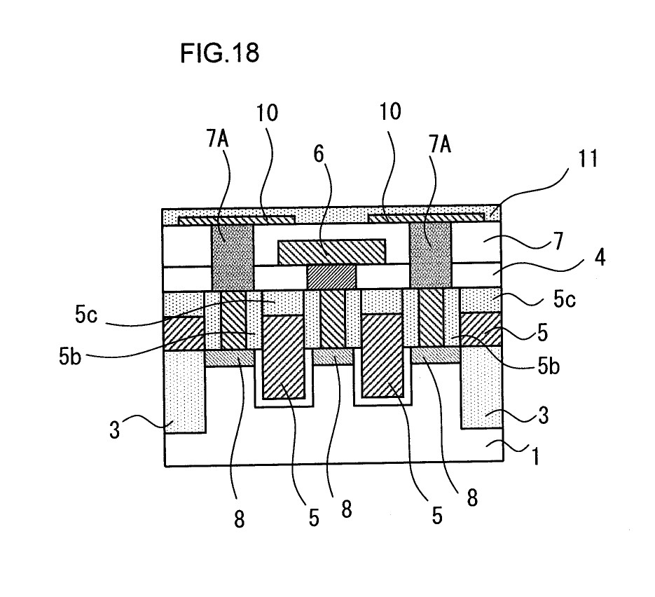

In a following time, as shown in FIG. 18, openings (contact holes) are formed at upper positions of substrate contact portions 205b, 205c as shown in FIG. 11 so as to penetrate through interlayer insulating films 4 and 7 and then expose the surface of substrate contact plugs 9. A stack film in which a W (tungsten) film is stacked on a barrier film such as a TiN/Ti film is deposited so as to fill the inner space of the openings, and then the surface of the resultant structure is polished away using the CMP method, thereby forming capacitive contact plugs 7A.

On interlayer insulating film 7, capacitive contact pads 10 are formed using a stack including a tungsten film. Capacitive contact pads 10 are electrically connected to capacitive contact plugs 7A and have larger size than that of the bottom of the lower electrodes of the capacitors as will be formed later. In the outer peripheral region of the memory cell section, as shown in FIG. 12B, capacitive contact pad 10 is disposed at the position corresponding to trench 12B as will be formed later. Thereafter, interlayer insulating film 11 (corresponding to a second interlayer insulating film in Claims) made of silicon nitride is formed with for example 60 nm thickness so as to cover capacitive contact pads 10.

FIG. 19 shows the resultant memory cell section and the bevel region. As shown in FIG. 19, the capacitive contact pad is not formed in region F containing bevel region as shown in FIG. 19B.

Next, as shown in FIG. 20, interlayer insulating film 12 (corresponding to a third interlayer insulating film) made of silicon oxide is formed with approximately 2 μm thickness using a PE-CVD (plasma enhanced CVD) method. Then, supporting film 14 is formed by depositing a silicon nitride film with approximately 100 nm using LP-CVD or ALD methods. As shown in FIG. 20B, supporting film 14 covers the side face and rear face of semiconductor substrate 1.

There is formed a hard mask layer used in forming openings 12A for forming the lower electrode of the capacitor. The hard mask layer has a stack structure of carbon film 21 and ARL (anti-reflect layer) 22. Carbon film 21 is formed with 600 to 800 nm thickness using the CVD method. ARL 22 acts as an anti-reflection film and is formed with 15 to 100 nm thickness using a SiON film. Otherwise, ARL may employ a stack structure in which an silicon oxide film is deposited on the SiON film. Material of ARL is selected to have different etching rate in the drying etching process from that of the carbon film because ARL may also function as a hard mask.

Thereafter, a mask pattern for forming openings 12A at a capacitor forming positions are formed by performing a photolithography method using photoresist film 23 on ARL. At this time, photoresist film 23 is formed up to region F out of the effective chip region whereas a normal mask pattern is not formed in bevel region D because the top face of semiconductor substrate 1 has a curved shape in bevel region D.

Next, as shown in FIG. 22, ARL 22 and carbon film 21 are patterned sequentially by performing an anisotropic dry etching using photoresist film 23 as a mask. In bevel region D, ARL 22 and carbon film 21 are partly removed away because photoresist film 23 collapses in bevel region D. in such a anisotropic dry etching, photoresist film 23 is etched away during dry etching of the carbon film because all of photoresist film 23 and carbon film 21 are made of organic materials. The shape of the mask pattern is sustained with ARL 22. The resulting mask pattern made of ARL 22 and carbon film 21 becomes a first mask pattern.

The DRAM chip being operable as circuit is formed in an inner region (effective chip region) excluding region F with a ring shape located at the outermost periphery of semiconductor substrate 1 as shown in FIG. 22B. In case a circular substrate with 300 nm diameter is used as the semiconductor substrate, the width of region F is set to approximately 2 mm. In region F of semiconductor substrate 1, the conductive film of capacitive contact pad 10 is removed away in the patterning process. In bevel region D, some of ARL 22 and carbon film 21 are removed away because the photoresist film pattern collapses.

In a following process, as shown in FIG. 23, ARL 22 is removed in a ring shape by width E1 from the outermost edge of semiconductor substrate 1. Such removal of ARL 22 is carried out by performing a dry etching using gas containing for example CF₄ and using a commercially-available dry etching apparatus being able to perform the dry etching of the bevel region. The dry etching apparatus being able to perform the dry etching of the bevel region may etch off in a dry manner only the ring shape region with predetermined width E1 in bevel region D. Here, width E1 is set to the width (smaller than 2 mm) smaller than the width of region F so that the effective chip region is not be etched away (for example, E1=1.8 mm). If it is assumed that etching width E1 variations are brought out in etching the bevel region, width E1 should be set with consideration of the maximum of the variations. In the region at which ARL 22 has been removed, carbon film 21 remains.

Next, as shown in FIG. 24, bevel mask layer 35 (corresponding to a second mask) is formed with width E2 from the outermost edge of semiconductor substrate 1 and over the end of interlayer insulating film 12 using the photoresist film formed in the ring shape. Here, in the radius direction of the semiconductor substrate, width E2 is set to be smaller than previously set width E1 (for example, E2=1.4 mm). It is more preferable that E2 is smaller than 2 mm. Bevel mask layer 35 may be formed by applying a negative photoresist film and exposing only the width E2 region in a ring shape using a commercially available periphery-exposing apparatus and then performing the development of the exposed film.

In this exemplary embodiment, bevel mask layer 35 may be formed, without performing the special curing treatment in order to provide mechanical strength for example as in Japanese Patent Laid-Open No. 2002-334879, in the same manner as the formation method of the conventional photoresist film used in other processes. Moreover, in that the negative photoresist film is used, it is possible to form bevel mask layer 35 easily by irradiating the light along and to the periphery of the semiconductor substrate while rotating the semiconductor substrate. In this exemplary embodiment, it is possible to suppress the rise of the manufacturing cost because an apparatus dedicated to and material specified in the formation of bevel mask layer 35 are not necessary.

Subsequently, as shown in FIG. 25, openings 12A (corresponding to capacitor holes) are formed by performing a dry etching using ARL 22 and carbon film 21 as a mask so as to penetrate through supporting film 14 and interlayer insulating films 12, 11. At the same time, trench 12B (refer to FIG. 10 and FIG. 12; and corresponding to a trench for guard ring) is formed in the outer circumference region of the memory cell section. In the bottoms of openings 12A and trench 12B, the top face of capacitive contact pads 10 is exposed. In the dry etching process for forming openings 12A, ARL 22 is also etched and removed away. The shape of the mask pattern is sustained with carbon film 21. In the bevel region, region of width E2 covered with bevel mask layer 35 is not subjected to the dry etching, and, protected. Hence, the film structure including supporting film 14 and interlayer insulating film 12 are suppressed from peeling off from the bevel region.

After forming openings 12A and trench 12B, carbon film 21 is removed with a plasma ashing method using oxygen gas. At the same time, bevel mask layer 35 made of the photoresist film and underlying carbon film 21 is also removed.

In this exemplary embodiment, bevel mask layer 35 is not subjected to the special curing treatment and therefore is easily removed using the conventional plasma ashing method. In bevel region D of semiconductor substrate 1, supporting film 14 and interlayer insulating film 12 are not etched but remain because the bevel mask layer 35 is formed.

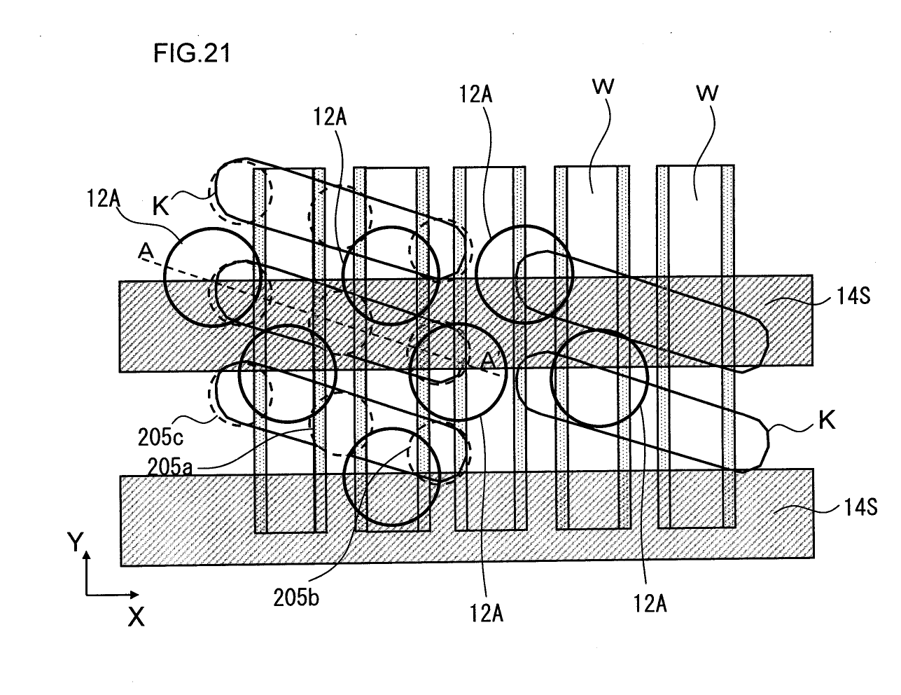

Thereafter, as shown in FIG. 26, a titanium nitride film as lower electrode 13 of the capacitor is formed with such thickness that the inner space of openings 12A is not completely filed with the titanium nitride film. FIG. 21 shows, in a top view manner, schematic formation positions of the capacitors relative to active regions K and word lines W. In FIG. 21, lower electrodes 13 of the capacitors are formed at the openings 12A positions. The material of the lower electrode may employ other metal films than the titanium nitride film. At the same time as the formation of the lower electrode in the memory cell section, lower electrode 13 is formed in trench 12B for guard ring. Lower electrode 13 over supporting film 14 is removed using the CMP method or etching-back and accordingly lower electrode 13 remain so as to cover the inner wall of openings 12A and trench 12B.

Next, support 14S is formed by patterning supporting film 14 using the pattern made of the photoresist film as a mask. Support 14S is in a contact with portions of the side face of lower electrode 13 so as to support the lower electrode, resulting in preventing the lower electrode from collapsing in a subsequent wet etching process. One example of arrangement pattern of support 14S is shown in FIG. 21.

The pattern of support 14S has a stripe shape extending in the X direction over the photoresist mask. Support 14S finally formed after the pattern is transferred from the photoresist mask remains only in the region out of openings 12A because silicon nitride film 14 is not formed in openings 12A from the beginning.

Support 14S couples each other neighboring lower electrodes in those extending direction and extends up to the end of the memory cell section. At the end of the memory cell section, support 14S is coupled to the side face of lower electrode 13 formed as the guard ring in trench 12B. Moreover, supporting film 14 covers the top face of a peripheral circuit section (52 in FIG. 9) and thus prevents chemical solution or etchant (hydrofluoric acid) from invading the peripheral circuit section out of the memory cell section during a subsequent wet etching.

Meanwhile, the shape and extending direction of support 14S are not limited to those as indicated in FIG. 21. Moreover, at least a portion of support 14S may overlap with each of openings 12A. At least a portion of support 14S contacts with the side wall of the lower electrode, thereby supporting the lower electrode. Furthermore, supporting film 14 may be patterned so that the position at which support 14S is in a contact with individual lower electrode 13 may be different between the plurality of the lower electrodes.

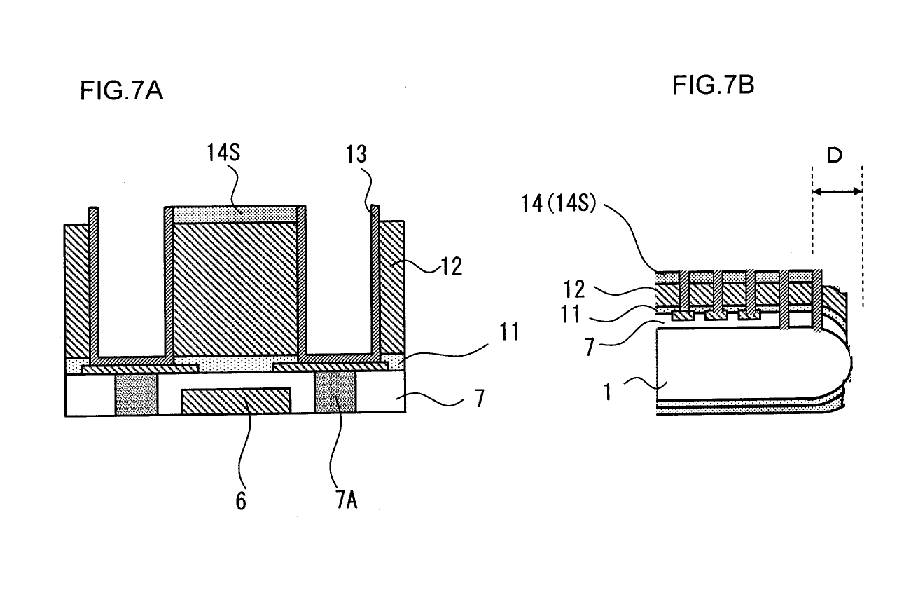

In bevel region D of the semiconductor substrate 1, the normal photoresist film pattern for forming support 14S is not formed because the top face of semiconductor substrate 1 is curved in bevel region D. In this exemplary embodiment, not as in the state of FIG. 7B as previously described, the bevel mask layer is provided, and, hence, supporting film 14 is not damaged at the time before the photoresist film pattern is formed, thereby suppressing the supporting film from being partially thinner or being partially lost. Accordingly, although the photoresist film pattern may collapse during pattering the supporting film, the area of the supporting film remaining finally may become larger than that in the conventional approach, resulting in preventing the reduction of the supporting strength relative to the lower electrode.

Thereafter, as shown in FIG. 27, by performing the wet etching using the chemical solution or etchant containing hydrofluoric acid, interlayer insulating film 12 is removed in the memory cell section, to expose the outer wall of lower electrode 13. In such a wet etching, interlayer insulating film 11 made of the silicon nitride film serves as a stopper film so as to prevent the underlying device from being etched.

In the region excluding the memory cell section, supporting film 14 deposited on the top face of interlayer insulating film 12 is not removed but remains and further the surface of the region is covered with lower electrode 13 and supporting film 14 formed as the guard ring in trench 12B, resulting in etchant used in the wet etching process from invading the region excluding the memory cell section. Lower electrode 13 of the capacitor is supported with support 14S in order to prevent the lower electrode from collapsing during the wet etching process.

In this exemplary embodiment, in bevel region D of semiconductor substrate 1, supporting film 14 never collapses but remains so as to support lower electrode 13. In this way, it is possible to prevent the lower electrode from collapsing and peeling off in the bevel region. Further, the fixing strength related to the supporting film itself may be kept on due to no pattern collapsing, thereby suppressing the peeling-off. As a result, it is possible to suppress reduction of the producing yield of the semiconductor device increase of the manufacturing cost thereof.

Next, capacitive insulating film (not shown) is formed so as to cover the side wall of lower electrode 13. The capacitive insulating film may include, in the way of an example, a high dielectric film such as an zirconium oxide (ZrO₂) film, an aluminum oxide (Al₂O₃), an hafnium oxide (HfO₂) film or a stack of those films.

Subsequently, as shown in FIG. 12, upper electrode 15 of the capacitor is formed using titanium nitride. The upper electrode may employ other metal films than the titanium nitride film. Otherwise, a stack film in which a polysilicon film is stacked on the titanium nitride film may be used as the upper electrode, thereby improving filling property into the spacing between the upper electrode 15 and lower electrode 13. The capacitive insulating film is sandwiched between the upper electrode 15 and lower electrode 13, resulting in forming capacitor Ca.

Thereafter, interlayer insulating film 40 is formed using silicon oxide. In the memory cell section, a drawn contact plug (not shown) is formed to supply voltage (plate voltage) to upper electrode 15 of the capacitor. The supporting film may be removed away in the peripheral circuit section in patterning the upper electrode because supporting film 14 formed in the peripheral circuit section is not necessary after the wet etching process. By removing away the supporting film in the peripheral circuit section, it is easy to perform the dry etching for forming the contact holes when providing the contact plugs connected to the electrodes of the MOS type transistor formed in the peripheral circuit section.

Next, upper wire layer 41 made of aluminum (Al) or copper (Cu) is formed and then surface protection film 42 is formed using silicon oxynitride (SiON), thereby completing the DRAM chip.

### Second Exemplary Embodiment

First, in this embodiment, processes taken until carbon film 21 and ARL 22 are patterned using the photoresist film as a mask in order to form openings 12A and trench 12B as shown in FIG. 22, are identical with those in the first exemplary embodiment.

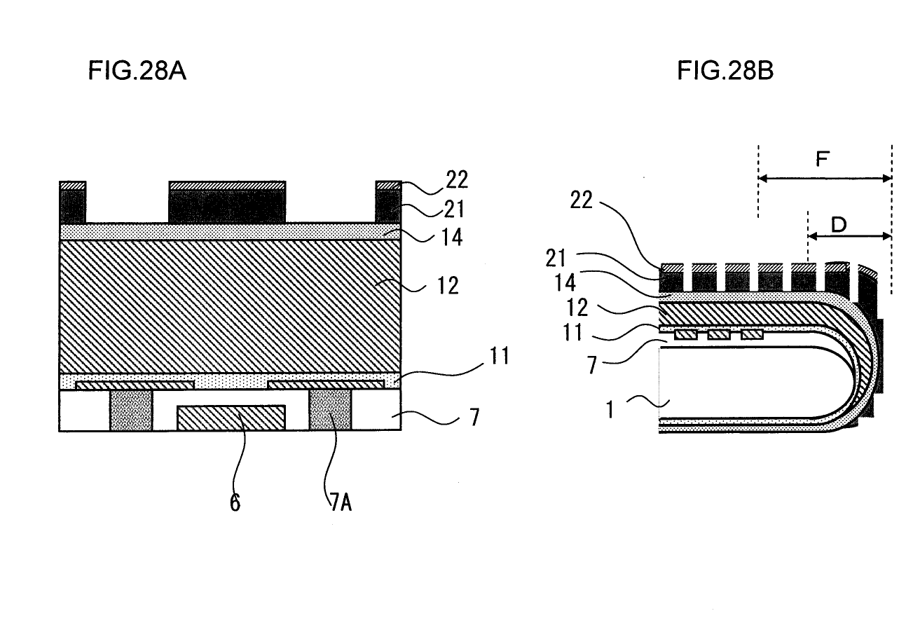

The DRAM chip which is operable as circuit is formed in an inner region (effective chip region) excluding region F with a ring shape located at the outermost periphery of semiconductor substrate 1 as shown in FIG. 28B. In case a circular semiconductor substrate with 300 nm diameter is used, the width of region F is set to approximately 2 mm. In region F, the conductive film of capacitive contact pad 10 is removed away in the patterning process. In bevel region D of semiconductor substrate 1, ARL 22 and carbon film 21 are partly removed away because of the photoresist film pattern collapses. ARL 22 and carbon film 21 correspond to a first mask.

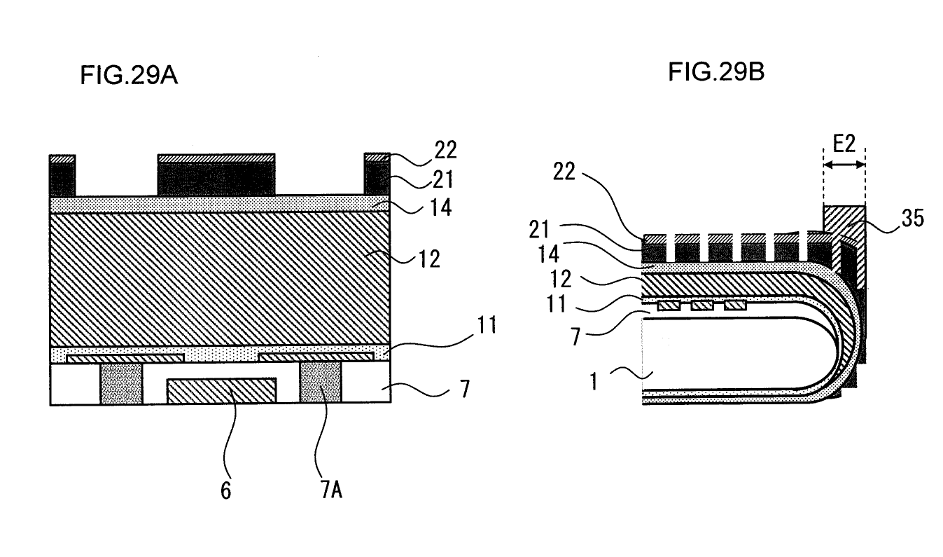

Next, as shown in FIG. 29, bevel mask layer 35 (corresponding to a second mask) is formed with width E2 from the outermost edge of semiconductor substrate 1 and over the end of interlayer insulating film 12 using the photoresist film formed in the ring shape. Here, in the radius direction of the semiconductor substrate, width E2 is set to be smaller than previously set width E1 (for example, E2=1.4 mm). It is more preferable that E2 is smaller than 2 mm. Bevel mask layer 35 is formed by applying a negative photoresist film and exposing only the width E2 region in a ring shape using a commercially available periphery-exposing apparatus and then performing the development of the exposed film.

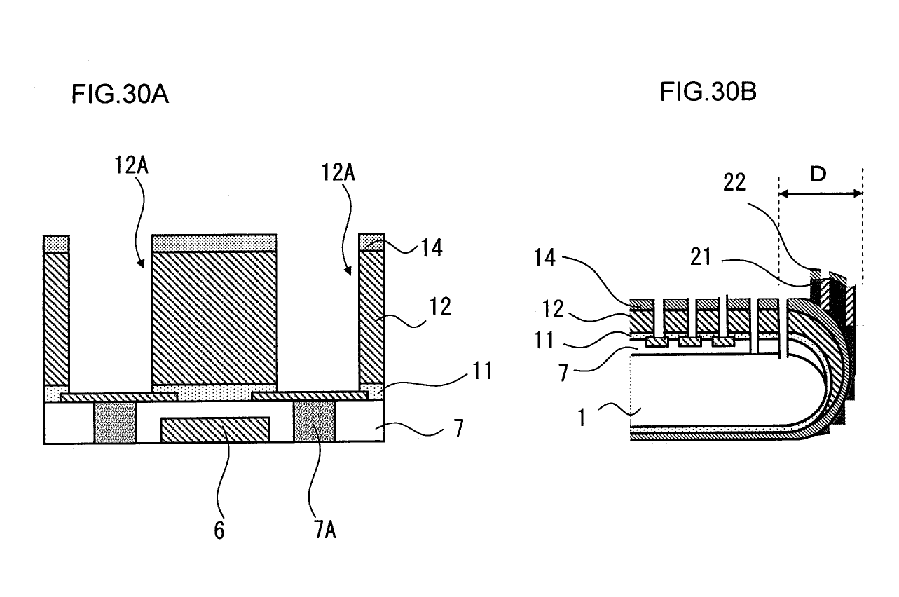

Subsequently, as shown in FIG. 30, openings 12A (corresponding to capacitor holes) are formed by performing an anisotropic dry etching using ARL 22 and carbon film 21 as a mask so as to penetrate through supporting film 14 and interlayer insulating films 12 (corresponding to a third insulating film) and interlayer insulating films 11 (corresponding to a second insulating film). At the same time, the trench 12B for guard ring is formed in the region out of the memory cell section. In the bottoms of openings 12A and trench 12B, the top face of capacitive contact pads 10 is exposed. In the dry etching process for forming openings 12A, ARL 22 is also etched and removed away. The shape of the mask pattern is sustained with carbon film 21. In the bevel region, width E2 region covered with bevel mask layer 35 is not subjected to the dry etching and protected.

After forming openings 12A and trench 12B, carbon film 21 is removed with a plasma ashing method using oxygen gas. At the same time, bevel mask layer 35 made of the photoresist film on ARL 22 are also partly removed. In the region covered with bevel mask layer 35, there remain ARL 22, carbon film 21 and a portion of bevel mask layer 35 filled between the carbon films.

In bevel region D of semiconductor substrate 1, supporting film 14 and interlayer insulating film 12 are not etched but remain because of the provision of bevel mask layer 35.

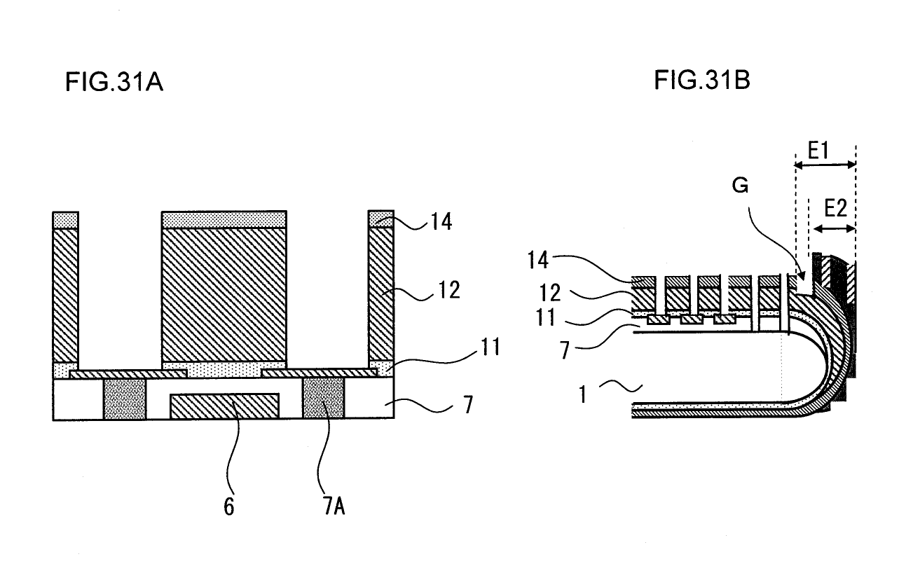

Thereafter, as shown in FIG. 31, ARL 22 is removed in a ring shape by width E1 from the outermost edge of semiconductor substrate 1. Such removal of ARL 22 is carried out by performing a dry etching using gas containing for example CF₄ and using a commercially-available dry etching apparatus being able to perform the dry etching of the bevel region. The dry etching apparatus being able to perform the dry etching of the bevel region may etch off in a dry manner only the ring shape region with predetermined width E1 in bevel region D. Here, width E1 is set to the width (smaller than 2 mm) smaller than the width of region F so that the effective chip region may not be etched away and further width E1 is set to the width larger than width E1 set in previously forming the bevel mask layer (for example, E1=1.6 mm). In this way, it is possible to secure overlapping margin in setting widths E1, E2 in order that ARL 22 is prevented from remaining. It is preferable that width E1 become as close to width E2 as possible while covering completely the width E2 region.

If it is assumed that etching width E1 variations are brought out in etching the bevel region, width E1 should be set with consideration of the maximum of the variations. In the region at which ARL 22 has been removed, the portions of carbon film 21 and a portion of bevel mask layer 35 remain. In a region G not covered with the bevel mask layer within the E1 region, the portions of supporting film 14 and interlayer insulating film 12 are also removed together with the removal of ARL 22. In this way, in the region G, a slit type opening is formed within supporting film 14.

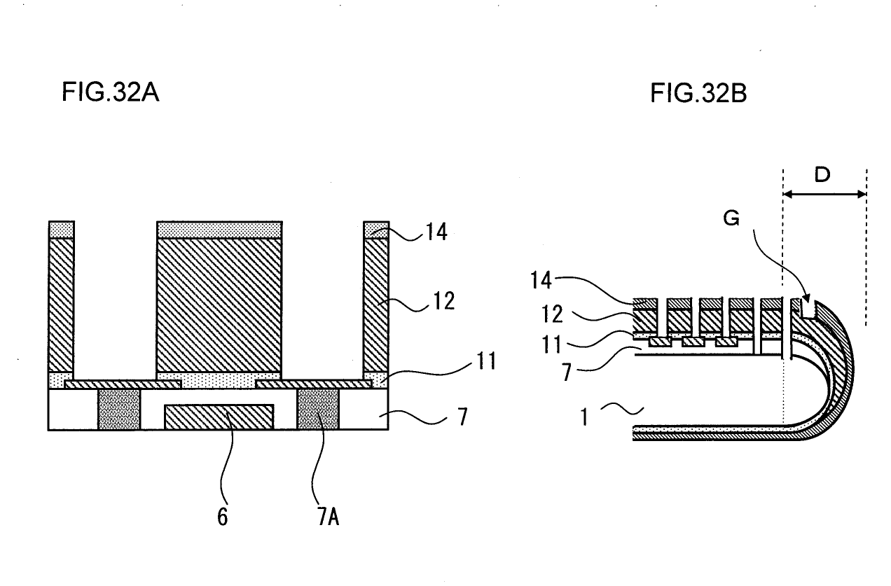

Next, as shown in FIG. 32, carbon film 21 and bevel mask layer 35 remaining in bevel region D are removed away by performing plasma ashing method using oxygen gas. In bevel region D of semiconductor substrate 1, supporting film 14 remains except at region G without being damaged.

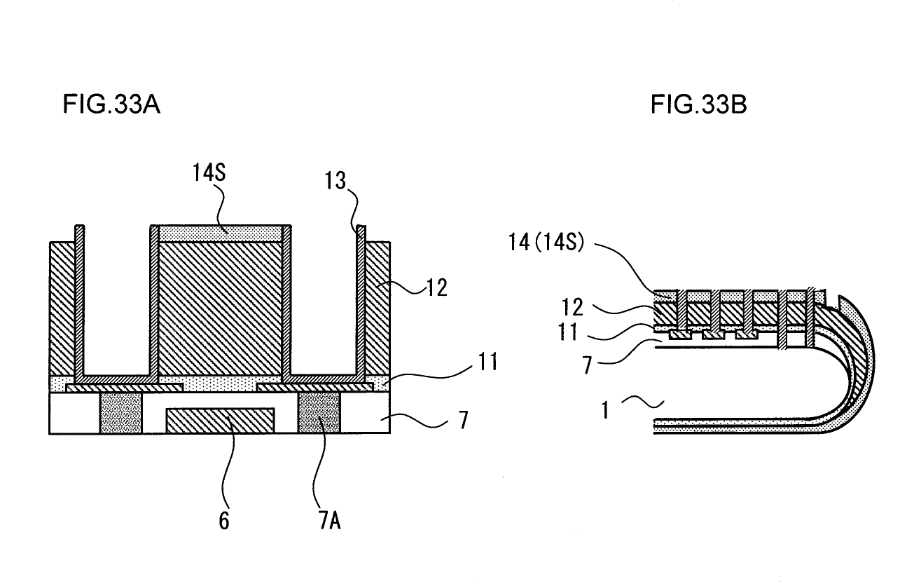

Thereafter, as shown in FIG. 33, a titanium nitride film as lower electrode 13 of the capacitor is formed with such thickness that the inner space of openings 12A is not completely filed with the titanium nitride film. FIG. 21 shows, in a top view manner, schematic formation positions of the capacitors relative to active regions K and word lines W. In FIG. 21, lower electrodes 13 of the capacitors are formed at the openings 12A positions. The material of the lower electrode may employ other metal films than the titanium nitride film. At the same time as the formation of the lower electrode in the memory cell section, lower electrode 13 is formed in trench 12B for guard ring.

Lower electrode 13 over supporting film 14 is removed away using the CMP method or etching-back and accordingly a portion of lower electrode 13 which covers the inner wall of openings 12A and trench 12B remains. Next, support 14S is formed by patterning supporting film 14 using the pattern made of the photoresist film as a mask. Support 14S is in a contact with portion of the side face of lower electrode 13 and supports the lower electrode, to prevent the lower electrode from collapsing in a subsequent wet etching process. One example of arrangement pattern of support 14S is shown in FIG. 21.

The pattern of support 14S has a stripe shape extending in the X direction over the photoresist mask. Support 14S finally formed after the pattern is transferred from the photoresist mask remains only in the region out of openings 12A because silicon nitride film 14 is not formed in openings 12A from the beginning.

Support 14S couples each other neighboring lower electrodes in those extending direction and extends up to the end of the memory cell section as shown in FIG. 10. At the end of the memory cell section, support 14S is coupled to the side face of lower electrode 13 formed as the guard ring in trench 12B. Moreover, supporting film 14 covers the top face of a peripheral circuit section (52 in FIG. 9) and thus prevents chemical solution or etchant (hydrofluoric acid) from invading the peripheral circuit section out of the memory cell section during a subsequent wet etching.

Meanwhile, as in the first exemplary embodiment, the shape and extending direction of support 14S are not limited to those as indicated in FIG. 21. Moreover, at least a portion of support 14S may overlap with each of openings 12A. At least a portion of support 14S is in a contact with the side wall of the lower electrode to support the lower electrode. Furthermore, supporting film 14 may be patterned so that the position at which support 14S is in a contact with individual lower electrode 13 may be different between the plurality of the lower electrodes.

In bevel region D of the semiconductor substrate 1, the normal photoresist film pattern for forming support 14S is not formed because the top face of semiconductor substrate 1 is curved in bevel region D. In this exemplary embodiment, not as in the state of FIG. 7B as previously described, the bevel mask layer is provided, and, hence, supporting film 14 is not damaged except at region G at the time before the photoresist film pattern is formed. Accordingly, although the photoresist film pattern may collapse during pattering the supporting film, the area of the supporting film remaining finally may become larger than that in the conventional approach, resulting in preventing the reduction of the supporting strength relative to the lower electrode. Moreover, the fixing strength of the supporting film itself may improve.

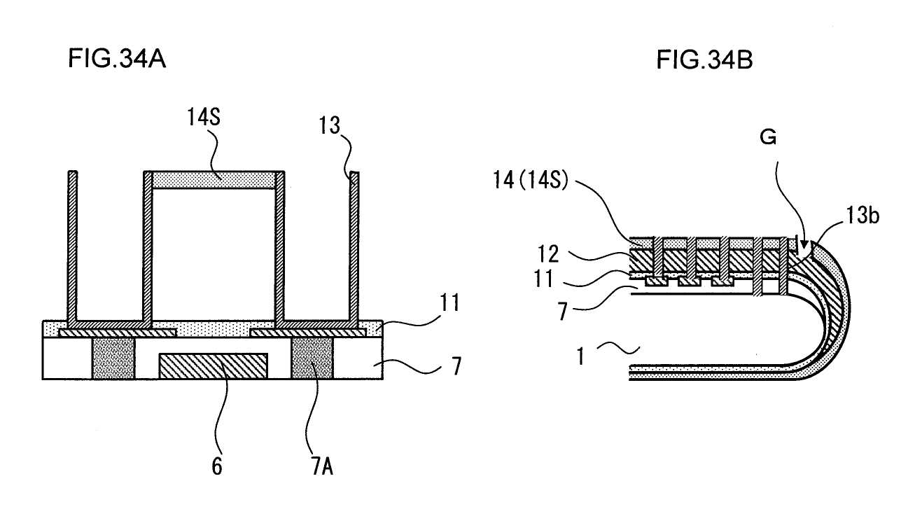

Thereafter, as shown in FIG. 34, by performing the wet etching using the chemical solution or etchant containing hydrofluoric acid, interlayer insulating film 12 is removed in the memory cell section, to expose the outer wall of lower electrode 13. In such a wet etching, interlayer insulating film 11 made of the silicon nitride film serves as a stopper film so as to prevent the underlying device from being etched.

In the region excluding the memory cell section, supporting film 14 deposited on the top face of interlayer insulating film 12 is not removed but remains and further the surface of interlayer insulating film 12 is protected with lower electrode 13 formed as the guard ring in trench 12B and support film 14, to prevent the etchant used in the wet etching process from invading the region excluding the memory cell section. Lower electrode 13 of the capacitor is supported with support 14S to prevent the lower electrode 13 from collapsing during the wet etching process.

In this exemplary embodiment, in bevel region D of semiconductor substrate 1, supporting film 14 never collapses but remains so as to support lower electrode 13. However, at region G, the supporting film gets opened in the slit shape and hence it is easy for lower electrode 13b to collapse and peel off at region G and its neighboring place. Region G is essentially located out of the effective chip region, and, thus, in its near place, the capacitive contact pad is not formed and lower electrode 13b is formed so as to penetrate through interlayer insulating film 11. For this reason, lower electrode 13b is supported with interlayer insulating film 11 made of the silicon nitride film, resulting in preventing lower electrode 13b from peeling off or collapsing.

Furthermore, in bevel region D of semiconductor substrate 1, the remaining amount of supporting film 14 according to the second exemplary embodiment becomes relatively larger than in the conventional approach (in FIG. 7). Accordingly, although suppressing extent of the peeling off may diminish at region G and its neighboring place, attachment rate of foreign materials due to the peeling off of the electrode and supporting film may reduce as a whole, comparative to the conventional approach. The processes after the formation of capacitive insulating film and upper electrode are identical with those in the first exemplary embodiment.

In the first exemplary embodiment, in case bevel region D is not sufficiently covered with carbon film 21 in removing ARL 22 in bevel region D as shown in FIG. 23, supporting film 14 is etched and damaged. For this reason, it is necessary to appropriately control the dry etching in removing ARL 22.

In contrast, in the second exemplary embodiment, the bevel region is covered with the carbon film and the remaining bevel mask layer, and, hence, the supporting film is protected securely, so that the supporting film is never damaged except at region G.

Subsequently, as in FIG. 12 of the first exemplary embodiment, capacitive insulating film (not shown) is formed so as to cover the side wall of lower electrode 13 and then upper electrode 15 of the capacitor is formed. The capacitive insulating film is sandwiched between the upper and lower electrodes, resulting in forming capacitor Ca.

Thereafter, interlayer insulating film 40 is formed using silicon oxide. In the memory cell section, a drawn contact plug (not shown) is formed to supply voltage (plate voltage) to upper electrode 15 of the capacitor. Next, upper wire layer 41 made of aluminum (Al) or copper (Cu) is formed and then surface protection film 42 is formed, thereby completing the DRAM chip.

### Third Exemplary Embodiment

This embodiment is different from the first embodiment in that in the first embodiment, the wet etching is performed instead of the dry etching in removing ARL 22 in the bevel region as shown in FIG. 23. Accordingly, below, only the wet etching process will be described and description of other processes than the wet etching process will be omitted because other processes than the wet etching process is the same as those of the first embodiment.

In order to remove ARL 22 in a ring shape by width E1 from the outermost edge of semiconductor substrate 1, the etchant containing hydrofluoric acid is injected into only the region with predetermined width E1 using the commercially available wet etching apparatus while rotating semiconductor substrate 1. ARL 22 is made of the SiON film, and, thus, supporting film 14 made of the silicon nitride (Si₃N₄) may be prevented from not damaged and ARL may be selectively removed. Moreover, in case bevel region D is not completely covered with carbon film 21, supporting film 14 may be prevented from being damaged, thereby suppressing the collapse of the pattern.

In accordance with this exemplary embodiment, the lower electrode and the supporting film may be prevented from peeling off in the most effective manner.

(Evaluation)

As for each of the above mentioned embodiments, attachment results of the foreign materials at the time when the outer wall of the lower electrode of the capacitor is exposed using the wet etching are checked using a test apparatus checking out the defects on the surface of the semiconductor substrate. The DRAM chips are formed using the following four methods in case of the semiconductor substrate with 300 mm diameter and then are compared with each other in terms of the defects.

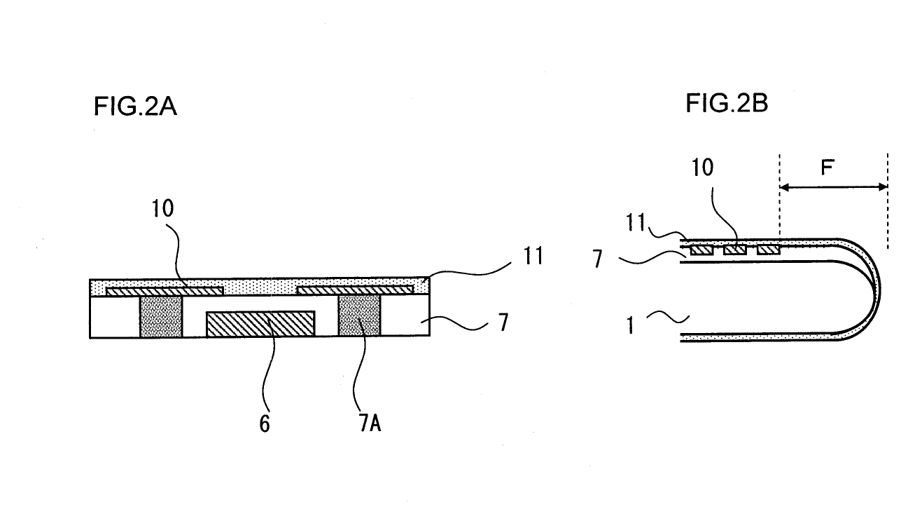

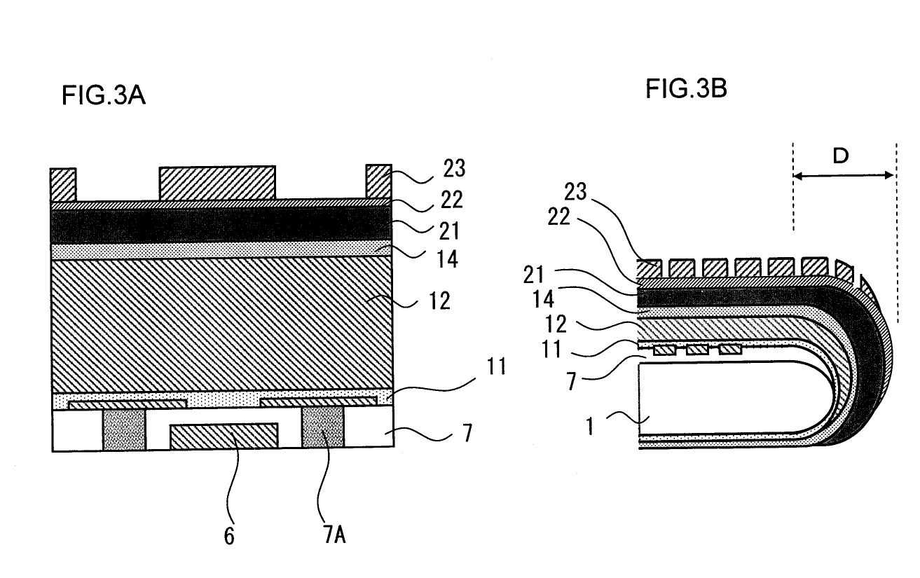

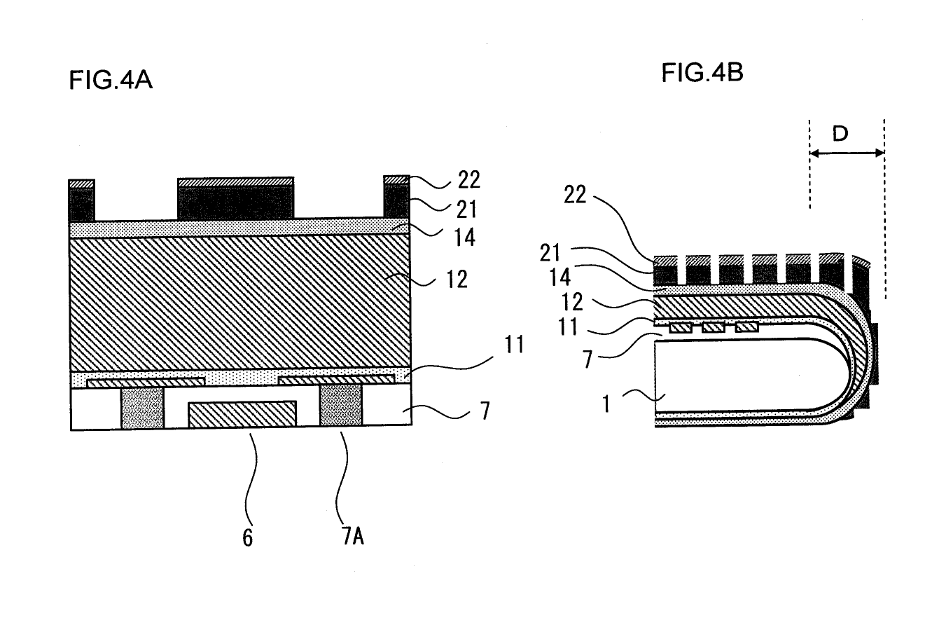

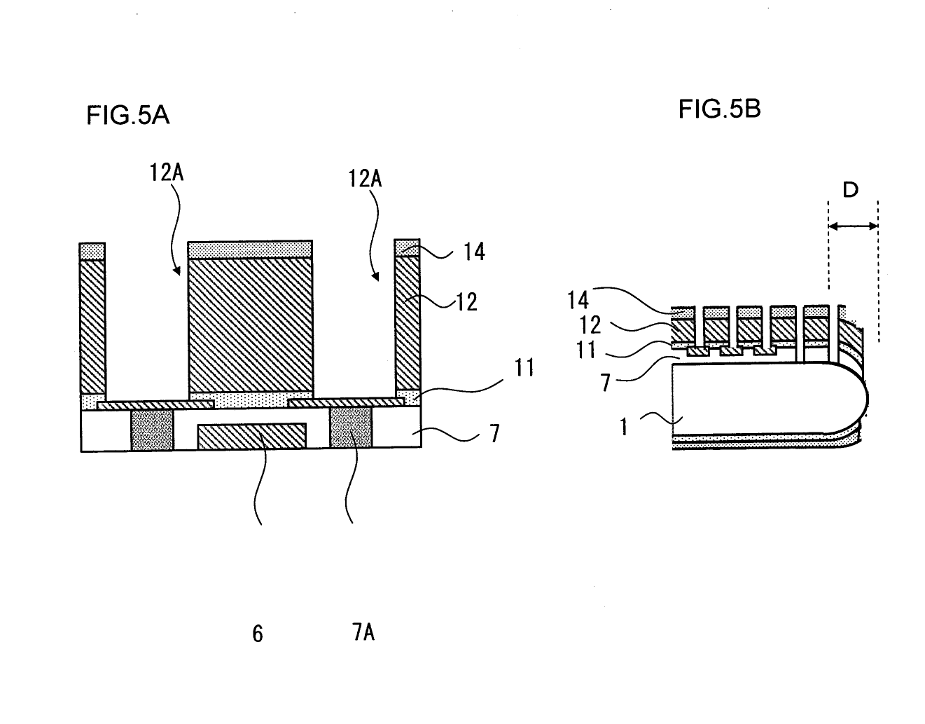

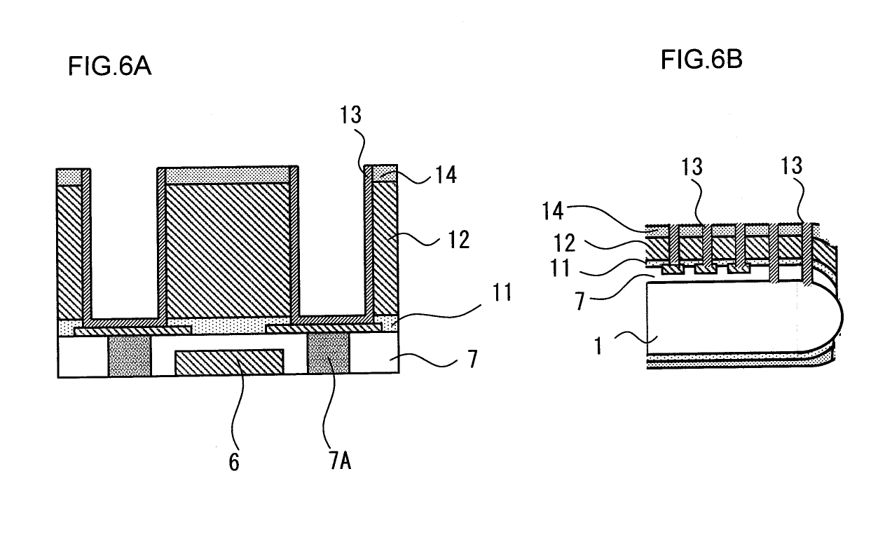

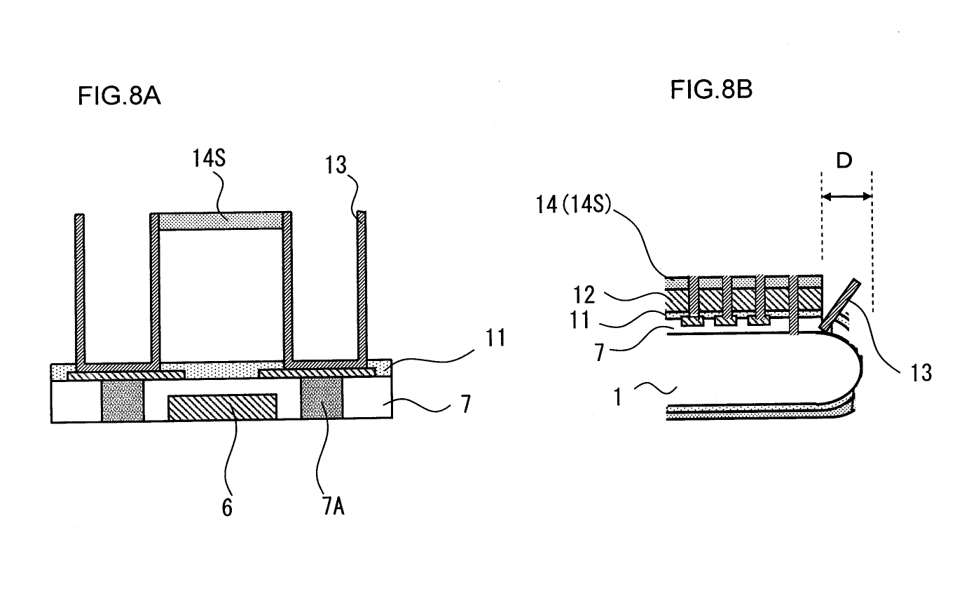

R: the conventional method (FIG. 2 to FIG. 8)

M1: the manufacturing method according to the first exemplary embodiment (FIG. 9 to FIG. 27)

M2: the manufacturing method according to the second exemplary embodiment (FIG. 28 to FIG. 34)

M3: the manufacturing method according to the third exemplary embodiment.

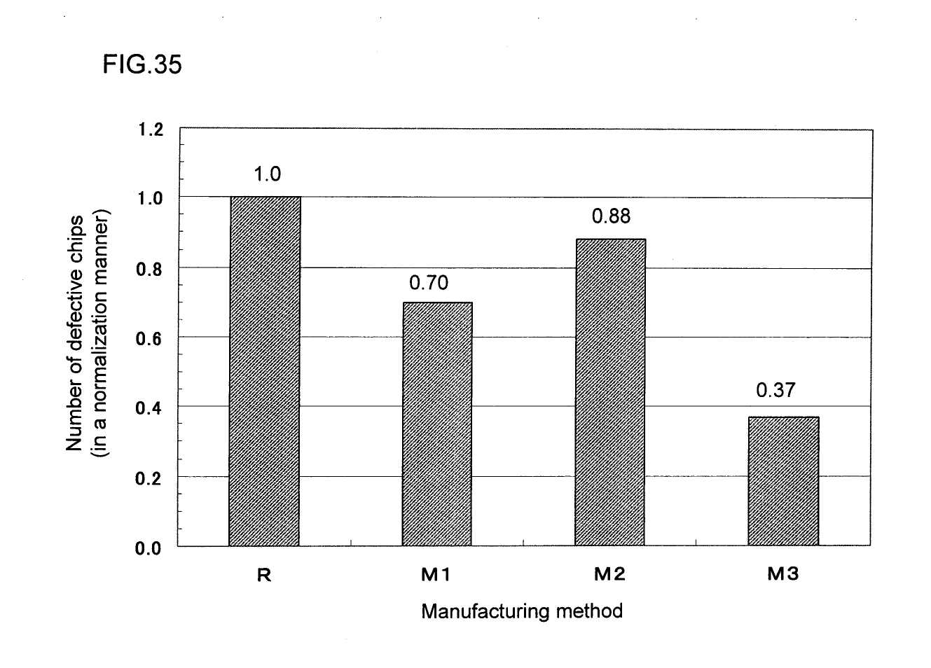

In the defects test, there are counted the number of the chips including the defects with sizes equal to or larger than 0.5 μm due to the attachment of the foreign materials among the DRAM chips. The defects include those resulting from other causes than the attachment of the capacitor electrode and supporting film. FIG. 35 shows the measurement results in terms of the number of the defective chips according to the above four methods. The vertical axis in FIG. 35 indicates the number of defective chips in a normalization manner in which the number of the defective chips on the semiconductor substrate using the conventional manufacturing method R is set to 1.

It is seen from FIG. 35 that all of the numbers of the defective chips on the semiconductor substrates formed using the first to third embodiments M1 to M3 become smaller compared to that using the conventional method R, resulting in the suppression of the attachment amount of the foreign materials resulting from the peeling-off. The most effective manner is the manufacturing method M3 according to the third exemplary embodiment. The number of the defective chips on the semiconductor substrates using the manufacturing method M2 according to the second exemplary embodiment becomes larger than that using the manufacturing method M1 according to the first exemplary embodiment. As mentioned above, it is conceivable that in the manufacturing method M2 according to the second exemplary embodiment, the silt shape opening is formed in the supporting film in the place near to the bevel region.

It is apparent that the present invention is not limited to the above embodiments, but may be modified and changed without departing from the scope and spirit of the invention.

What is claimed is:

1. A method of manufacturing a semiconductor device, comprising:
preparing a semiconductor substrate;
forming a film structure comprising at least one film on a primary face comprising a bevel region of the semiconductor substrate;
forming a first mask with a pattern on a face of the film structure;
forming a second mask over the bevel region so as to cover the first mask;
etching the film structure using the first and second masks so that the film structure remains in the bevel region and a region of the semiconductor substrate other than the bevel region; and
removing the first and second masks which remain.

2. The method of claim 1,
wherein the second mask covers the first mask over the bevel region and the first mask is exposed on a region of the semiconductor substrate excluding the bevel region.

3. The method of claim 2,
wherein the semiconductor substrate is a circular substrate and the second mask has a width smaller than 2 mm in a radius direction of the semiconductor substrate.

4. The method of claim 1,
wherein the second mask is made of negative photoresist.

5. The method of claim 1,
wherein in forming the first mask, a carbon film and an anti-reflection film are formed in this order from the film structure, as the first mask.

6. The method of claim 5, further comprising, between forming the first mask and forming the second mask, removing the anti-reflection film over the bevel region to expose the carbon film,
wherein in forming the second mask, the second mask is formed so as to cover a portion of the exposed carbon film over the bevel region;
in etching the film structure, the anti-reflection layer not covered with the second mask is removed together with the film structure using the etching; and
in removing the first and second masks, the second mask and the carbon film which remain are removed.

7. The method of claim 6,
wherein in removing the anti-reflection film over the bevel region, the anti-reflection film is selectively removed using a wet etching.

8. The method of claim 6,
wherein the anti-reflection film is made of a film containing silicon oxynitride (SiON) and
wherein in removing the anti-reflection film over the bevel region, the anti-reflection film is selectively removed by performing a dry etching using carbon tetrafluoride (CF₄) gas.

9. The method of claim 6,
wherein in removing the first and second masks, and the carbon film and the second mask are removed by performing plasma ashing using oxygen gas.

10. The method of claim 5,
wherein in forming the second mask, the second mask is formed so as to cover the carbon film and the anti-reflection film over the bevel region;
in etching the film structure, the anti-reflection layer not covered with the second mask is removed together with the removal of the film structure; and
the removing of the first and second masks comprises:
removing the carbon film not covered with the second mask and a portion of the second mask over the bevel region, to expose the anti-reflection layer over the bevel region;
removing the anti-reflection layer over the bevel region; and
removing the carbon film and the second mask remaining over the bevel region.

11. The method of claim 10,
wherein in removing the anti-reflection layer over the bevel region, a portion of a film included in the film structure is removed together with the removal of the anti-reflection layer by performing a dry etching of a region having a predetermined width from an outer edge of the semiconductor substrate and including the anti-reflection film and a portion of the film structure over the bevel region.

12. The method of claim 1,
wherein the semiconductor substrate comprises a MOS type transistor which is provided in a region excluding the bevel region of the semiconductor substrate and includes first and second impurities diffusion layers; and
wherein the film structure comprises a first insulating film, a second insulating film, a third insulating film and a supporting film in this order over the semiconductor substrate and comprises a pad electrically connected to the first impurities diffusion layer of the MOS type transistor, in the second insulating film.

13. The method of claim 12,
wherein the etching of the film structure comprises forming a hole so as to penetrate through the second and third insulating films and the supporting film to expose the pad; and
wherein the method further comprises, after removing the first and second masks:
forming a lower electrode in the hole; and
forming a capacitive insulating film and an upper electrode in this order on the lower electrode, to obtain a capacitor.

14. The method of claim 13,
wherein in forming the hole, a trench for guard ring is formed so as to surround a region in which the hole is formed and so as to penetrate through the second and third insulating films and the supporting film at the same time as the formation of the hole; and
in forming the lower electrode, a lower electrode covering an inner wall of the trench for guard ring is formed, at the same time as the formation of the lower electrode.

15. The method of claim 14, further comprising between forming the lower electrode and forming the capacitive insulating film and the upper electrode:
removing a portion of the supporting film located in the region surrounded with the trench for guard ring, to form an opening; and
performing a wet etching using the supporting film as a mask, to remove the third insulating film located in the region surrounded with the trench for guard ring.

16. A method of manufacturing a semiconductor device, comprising:
forming an interlayer insulating film on a semiconductor substrate;
sequentially depositing a carbon film and an anti-reflection film on a face of the interlayer insulating film and then patterning the deposited films, to form a first mask;
removing the anti-reflection film over a bevel region of the semiconductor substrate, to expose the carbon film;
forming a second mask containing a negative photoresist film so as to cover a portion of an exposed carbon film in the bevel region of the semiconductor substrate;
performing a dry etching using a mask pattern formed in the first mask, to pattern the interlayer insulating film in a region not covered with the second mask; and
removing the first and second masks which remain.

17. The method of claim 16,
wherein the interlayer insulating film is made of a silicon oxide film.

18. The method of claim 16,
wherein in removing the anti-reflection film over the bevel region, the anti-reflection film is removed using a dry etching or a wet etching.

19. A method of manufacturing a semiconductor device, comprising:
forming an interlayer insulating film on a semiconductor substrate;
sequentially depositing a carbon film and an anti-reflection film on a face of the interlayer insulating film and then patterning the deposited films, to form a first mask;
forming a second mask containing negative photoresist on the first mask over a bevel region of the semiconductor substrate;
patterning the interlayer insulating film using the first and second masks as a mask;
removing the anti-reflection layer in a region of the semiconductor substrate not covered with the second mask;
removing the carbon film in a region of the semiconductor substrate not covered with the second mask, and removing a portion of the second mask to expose the anti-reflection layer over the bevel region;
removing the anti-reflection layer exposed over the bevel region; and
removing the carbon film and the second mask remaining over the bevel region.

20. The method of claim 19,
wherein in removing the anti-reflection layer exposed over the bevel region, a portion of a film included in the film structure is removed together with the removal of the anti-reflection layer by performing a dry etching of a region having a predetermined width from an outer edge of the semiconductor substrate and including the anti-reflection film and a portion of the film structure over the bevel region.
